(19) United States
(12) Patent Application Publication
(10) Pub. No.: US 2025/0384320 A1
(43) Pub. Date: Dec. 18, 2025

(54) MULTI-PORT COHERENCE ELEMENT FOR QUANTUM INFORMATION DEVICE

(71) Applicants: LOCKHEED MARTIN CORPORATION, Bethesda, MD (US); UNIVERSITY OF TWENTE, Enschede (NL); SABANCI UNIVERSITY, Istanbul (TR)

(72) Inventors: Danielle Marie COUGER, Denver, CO (US); Rodolfo SALAS, Coppell, TX (US); Inanc ADAGIDELI, Istanbul (TR); Alexander BRINKMAN, Enschede (NL); Sofie KOLLING, Enschede (NL); Ahmet Mert BOZKURT, Istanbul (TR)

(21) Appl. No.: 19/113,407

(22) PCT Filed: Apr. 7, 2023
(86) PCT No.: PCT/US2023/017865

§ 371 Date: Aug. 20, 2025

(51) Int. Cl. G06N 10/40

(52) U.S. Cl. CPC G06N 10/40

(57) ABSTRACT

A system comprising a quantum information engine (QIE). The QIE includes a topological surface state three-dimensional topological insulator (TSS-3DTI) to flow, in a first flow direction from an input side to an output side, electrons having a first spin-momentum. The TSS-3DTI includes a first surface. The first surface has first spin-momentum locked charge carriers and a plurality of first magnetic impurities having a second average nuclear spin polarization. The TSS-3DTI stores information in the first surface at the points of interaction that occur between the plurality of first magnetic impurities interacting with the flowing electrons to exchange, at each point of interaction, a nuclear spin of a respective first magnetic impurity with an electron spin of a respective flowing electron. The system can include at least one surface. The system can harvest energy from other integrated circuits. A method of storing quantum energy is also provided.

### CROSS-REFERENCE TO RELATED APPLICATIONS

This application claims priority benefit of U.S. Provisional Application No. 63/328,657, titled “MULTI-PORT COHERENCE ELEMENT FOR QUANTUM INFORMATION DEVICE,” filed Apr. 7, 2022, which is incorporated herein in its entirety.

### BACKGROUND

Embodiments generally relate to quantum energy storage, for example, a quantum information engine for storing energy in nuclear quantum spins.

Current technologies for highly portable power systems can store energy in the form of unreacted electrochemical components with potentials of a few electron volts per reaction. This limits the specific energy of such systems to a few megajoules per kilogram. Nuclear battery concepts can achieve a specific energy increase over electrochemical concepts, but at the cost of ionizing radiation dangers, poor specific power by comparison to electrochemical solutions, and posing proliferation risks.

Techniques to store entropy rather than energy and to use entropy to improve energy harvesting from low quality sources have been proposed. For example, U.S. Publication No. 2011/0252798, which is incorporated by reference in its entirety herein, describes systems and methods that use stored entropy to harvest energy using a “quantum heat engine” (QHE). As other examples, U.S. Pat. Nos. 10,529,906 and 10,886,453, which are both also incorporated by reference in their entirety herein, describe other systems and methods for storing and using quantum energy.

Quantum heat engines produce work using quantum matter as their working substance. A variety of theoretical QHEs have been proposed, such as those described in Scully et al., “Using Quantum Erasure to Exorcize Maxwell's Demon: I. Concepts and Context,” Physica E 29 (2005) 29-39; Rostovtsev et al., “Using Quantum Erasure to Exorcise Maxwell's Demon: II. Analysis,” Physica E 29 (2005) 40-46; Ramandeep S. Johal, “Quantum Heat Engines and Nonequilibrium Temperature,” Quant. Ph., 4394v1, September 2009; and Yeo et al., “Quantum Heat Engines and Information,” Quant. Ph., 2480v1, August 2007, each of which is incorporated herein by reference in its entirety. These theoretical quantum heat engines, however, can be impractical or impossible to reduce to practice and can be limited to use with either interacting or non-interacting working fluids and can be limited to use with either classical thermal reservoirs or quantum reservoirs.

Accordingly, there is a continued desire for improved quantum information engines.

### SUMMARY

Embodiments generally relate to quantum energy storage, for example, a quantum information engine for storing energy in nuclear quantum spins.

An aspect of the embodiments includes a system comprising a quantum information engine (QIE). The QIE includes a topological surface state three-dimensional topological insulator (TSS-3DTI) to flow, in a first flow direction from an input side to an output side, electrons having a first spin-momentum. The TSS-3DTI includes a first surface. The first surface has first spin-momentum locked charge carriers and a plurality of first magnetic impurities having a second average nuclear spin polarization. The TSS-3DTI stores information in the first surface at the points of interaction that occur between the plurality of first magnetic impurities interacting with the flowing electrons to exchange, at each point of interaction, a nuclear spin of a respective first magnetic impurity with an electron spin of a respective flowing electron.

Another aspect of the embodiments includes an electronic device that includes at least one electrical circuit. The electronic device includes a system with a quantum information engine that is coupled to the at least one electrical circuit. The quantum information engine includes a topological surface state three-dimensional topological insulator.

An aspect of the embodiments includes a method for quantum energy storage. The method includes flowing electrons in a flow direction along a first surface of a quantum information engine (QIE) of the system. The QIE includes a topological surface state three-dimensional topological insulator (TSS-3DTI). The method includes storing information in the first surface at points of interaction that occur between a plurality of first magnetic impurities interacting with the flowing electrons to exchange, at each point of interaction, a nuclear spin of a respective first magnetic impurity with an electron spin of a respective flowing electron.

### BRIEF DESCRIPTION OF THE DRAWINGS

A more particular description briefly stated above will be rendered by reference to specific embodiments thereof that are illustrated in the appended drawings. Understanding that these drawings depict only typical embodiments and are not therefore to be considered to be limiting of its scope, the embodiments will be described and explained with additional specificity and detail through the use of the accompanying drawings in which:

FIG. 1 illustrates a top view of a schematic diagram of a system with a topological surface state three-dimensional topological insulator (TSS-3DTI);

FIG. 2A shows a schematic diagram a TSS-3DTI of FIG. 1 with two surfaces and metallic leads;

FIG. 2B shows a schematic diagram of a TSS-3DTI of FIG. 1 and multiple contacts on the metallic leads;

FIG. 2C shows a schematic diagram of a TSS-3DTI of FIG. 1 with at least three surfaces and metallic leads;

FIG. 3A illustrates a diagram of the dispersion relation for the surface states of a TSS-3DTI;

FIG. 3B illustrates the sign of the spin chirality changes for the surface states with energy E<0 below the Dirac point E=0;

FIG. 3C illustrates the sign of the spin chirality changes for the surface states with energy above the Dirac point E=0;

FIG. 4 illustrates a graphical representation of the normalized scattering probability of the surface states as a function of the relative angle ISB for process without spin-flip and with spin-flip;

FIG. 5A illustrates a diagram of the self-energy for the nonmagnetic impurity scattering. The dashed line indicates the averaging over the positions of the impurities;

FIG. 5B illustrates a diagram of the self-energy for the nuclear spin scattering, where the wiggly line is the nuclear spin correlators;

FIG. 6 illustrates a diagrammatic representation of the lesser component of the nuclear spin self-energy;

FIG. 7A illustrates a grid model circuit used as first approximation of QIE operation in a 2D surface state according to an embodiment;

FIG. 7B illustrates a schematic diagram of a system with a TSS-3DTI with a grid model circuit of FIG. 7A on the top and bottom surfaces;

FIG. 7C illustrates electron flow along a first surface of the TSS-3DTI of the system in FIG. 7B;

FIGS. 8A-8I illustrate electron interaction associated with the electron flow along a first surface of the system in FIG. 7C;

FIG. 9 illustrates a Frequency response of an isolated QIE, using ζ=0.1, in units of h/e²;

FIGS. 10A and 10B illustrate graphical representations of real and complex impedance of an 80×20 QIE grid compared to a single QIE device;

FIG. 10A illustrates a graph of Z_{QIE} normalized by h/e², corresponding to ballistic conductance;

FIG. 10B illustrates a graph of Z_{QIE} normalized by its low-frequency value, showing overlapping results for the grid and isolated device;

FIG. 11 illustrates a graph of the effect of varying the QIE grid size (Nₓ×N_{y}) on the scaling factor between the grid impedance and single device impedance;

FIG. 12A illustrates an equivalent configurations of LRR-circuits, with frequency response equal to the QIE in a parallel configuration;

FIG. 12B illustrates an equivalent configurations of LRR-circuits, with frequency response equal to the QIE in a series configuration;

FIG. 13 illustrates an equivalent circuit model, where the topological surface state is represented by two resistors, a series coupled resistor and an inductor in parallel;

FIG. 14 illustrates a frequency response of the real part and imaginary part of Z_{TSS};

FIG. 15 illustrates a graph of resistor Rₛₑᵣᵢₑₛ and resistor Rₛₕᵤₙₜ of the equivalent circuit model of FIG. 13;

FIG. 16 illustrates a graph of a quality factor as a function of ζ^{3D};

FIGS. 17A and 17B illustrate a quantitative estimate of the induced current as a function of time, on a topological surface of (Biᵢ₋ₓSbₓ)₂Te₃, with width WW=200 μm, length LL =500 nm, lₑₗ=10 nm, γ₀=3.3-10⁻¹² at T=3 K, where FIG. 17A is a graph of a mean polarization and FIG. 17B is a graph of current I_{MD};

FIG. 18A is an electronic circuit with a system having a topological surface state three-dimensional topological insulator;

FIG. 18B is an electronic circuit with a system having a surface-state three-dimensional topological insulator that is integrated on-chip; and

FIG. 19 shows an embodiment of a method for quantum energy storage.

### DETAILED DESCRIPTION

Embodiments are described herein with reference to the attached figures wherein like reference numerals are used throughout the figures to designate similar or equivalent elements. The figures are not drawn to scale and they are provided merely to illustrate aspects disclosed herein. Several disclosed aspects are described below with reference to non-limiting example applications for illustration. It should be understood that numerous specific details, relationships, and methods are set forth to provide a full understanding of the embodiments disclosed herein. One having ordinary skill in the relevant art, however, will readily recognize that the disclosed embodiments can be practiced without one or more of the specific details or with other methods. In other instances, well-known structures or operations are not shown in detail to avoid obscuring aspects disclosed herein. The embodiments are not limited by the illustrated ordering of acts or events, as some acts may occur in different orders and/or concurrently with other acts or events. Furthermore, not all illustrated acts or events are required to implement a methodology in accordance with the embodiments.

Notwithstanding that the numerical ranges and parameters setting forth the broad scope are approximations, the numerical values set forth in specific non-limiting examples are reported as precisely as possible. Any numerical value, however, inherently contains certain errors necessarily resulting from the standard deviation found in their respective testing measurements. Furthermore, unless otherwise clear from the context, a numerical value presented herein has an implied precision given by the least significant digit. Thus, a value 1.1 implies a value from 1.05 to 1.15. The term “about” is used to indicate a broader range centered on the given value, and unless otherwise clear from the context implies a broader range around the least significant digit, such as “about 1.1” implies a range from 1.0 to 1.2. If the least significant digit is unclear, then the term “about” implies a factor of two, e.g., “about X” implies a value in the range from 0.5× to 2×, for example, about 100 implies a value in a range from 50 to 200. Moreover, all ranges disclosed herein are to be understood to encompass any and all sub-ranges subsumed therein. For example, a range of “less than 10” can include any and all sub-ranges between (and including) the minimum value of zero and the maximum value of 10, that is, any and all sub-ranges having a minimum value of equal to or greater than zero and a maximum value of equal to or less than 10, e.g., 1 to 4.

### Global Definitions

The term h is Plank's constant.

The term h (modified form of Plank's constant h) is called h-bar and equals h/2π.

The term k_{B} is the Boltzmann constant defined as 1.380649×10⁻²³J·K⁻¹.

The term k_{B}T In 2 is Landauer's limit, where T is absolute the temperature of the system in Kelvins K and ln 2 is the natural logarithm of 2.

The term charge carrier as used herein refers to electrons.

The embodiments herein provide on-chip energy storage device that have controlled self-discharging, energy density, and life cycles.

The embodiments herein provide a localized high-density energy storage device for portable, micro-electronic devices with faster than state of the art discharge timescales specifically for low-power applications.

The method may include connecting loads so that the polarized nuclear spins will then induce currents aligned to their respective electron channels causing opposite spin electrons to scatter, depolarizing the nuclear spins and discharging the device.

The embodiments herein expand upon the two-dimensional topological insulator (2DTI) with one-dimensional (1D) edges to create a topological surface state three-dimensional topological insulator (TSS-3DTI) where the surface states of TSS-3DTIs exhibit necessary ingredient for a Maxwell's demon implementation; that is the backscattering of the surface states is only possible via spin-flip scattering with the nuclear spins.

The electron discharge is along the charging flow and thereby exhibits inductive behavior.

In some embodiments, the system can include at least one surface for storing information. In some embodiments, multiple surfaces of a single TSS-3DTI may be used to store information. These surfaces may be parallel and/or perpendicular to other surfaces, for example.

The system may be configured to harvest energy from other integrated circuits (ICs).

The inventors have determined that further characterization of these types of materials have demonstrated non-trivial series and shunt resistances that could inhibit direct scaling of the geometry. In order to maximize the information storage, the embodiments herein expand on a mesh of 1D devices to cover a 2D surface and specifically, a top surface and a bottom surface. Each surface maintains similar spin-polarized conductivity channels as with the 1D device, but these channels are now as wide as the width of the 1D device's surface. Because of the diffusive and random nature of the individual electron's motion, the coupling efficiency to the nuclear spins is slightly weaker than the 1D helical edge states, but the significant increase in the available nuclear spins compensates for this deficiency by increasing the probability of scattering and coupling. This compensation leads to even larger density of information and energy storage compared to the 1D analogue. Furthermore, by introducing multiport contacts to the material, the information stored could be used to drive currents to loads in different contacts than those used to charge the device, thus resembling a multiplexing power supply switch.

In some embodiments, an electronic device is included that has logic circuitry to control a quantum information engine (QIE). For purpose of illustration and not limitation, the electronic device can be one of an application specific integrated circuit (ASIC), a power amp (PA), a focal plane array (FPA), a radar transmitter, a mobile phone, a mobile computer device, an electric motor on an aircraft, or at least a part thereof.

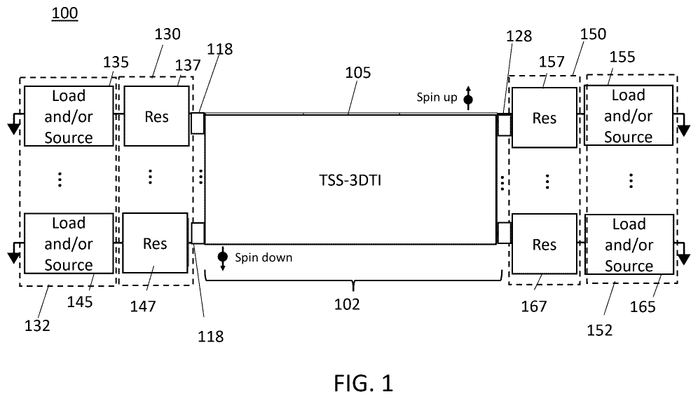

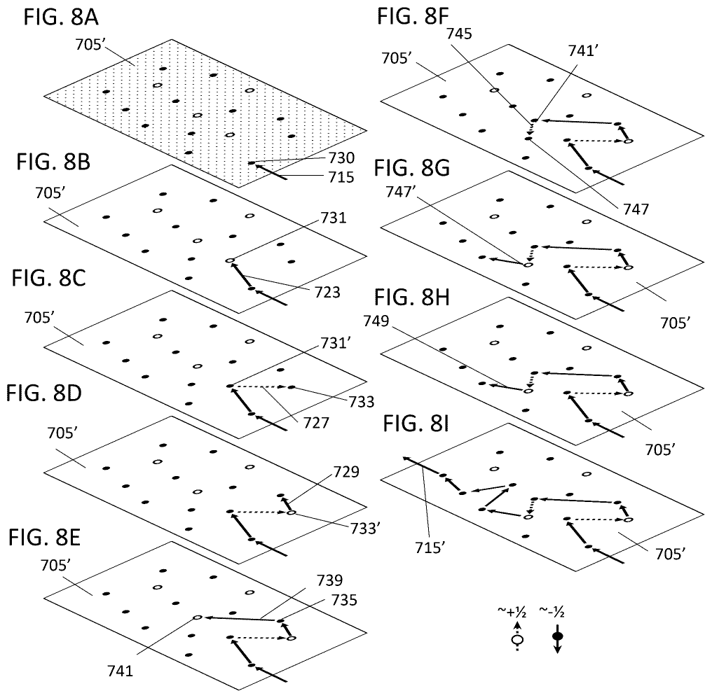

FIG. 1 illustrates a top view of a schematic diagram of a system 100 with a TSS-3DTI 102. The TSS-3DTI 102 may be a quantum information engine (QIE) that is configured to be an inductive energy storage device due to coupling between electron spins in a topological surface state and the nuclear spins of the magnetic impurities. As shown in FIG. 1, the TSS-3DTI 102 may have at least one of nuclear spins and magnetic impurities that allow electrons to spin-flip with regular scattering or backscattering, as described in more detail later in relation to FIGS. 8A-8I.

A TSS-3DTI 102 may include at least one surface 105 to flow electrons in a first flow direction from an input side to an output side. The electrons have a first spin-momentum. The surface 105 may sometimes be referred to as a “first surface.” The TSS-3DTI includes a first surface 105 with first spin-momentum locked charge carriers and plurality of first magnetic impurities with a second average nuclear spin polarization. Specifically, the first surface 105 is doped with a plurality of first magnetic impurities with a second average nuclear spin polarization. The first surface 105 is doped with a plurality of first magnetic impurities with a first average nuclear spin polarization where an electron with the first spin momentum does not spin flip in response to an interaction with the first magnetic impurities with the first average nuclear spin polarization of the first surface. The electrons flowing on the first surface 105 of TSS-3DTIs propagate in any direction on the surface, and these electrons do not have a definite spin quantization axis. Accordingly, the average nuclear spin polarization is not directly “spin-up”or “spin-down,” but instead an average relative to one of the “spin-up” spin quantization axis and “spin-down” spin quantization axis, for example.

The TSS-3DTI 102 to flow, in a first flow direction from an input side to an output side, electrons having a first spin-momentum. The TSS-3DTI includes a first surface, for example that has first spin-momentum locked charge carriers and a plurality of first magnetic impurities having a second average nuclear spin polarization. The TSS-3DTI 102 stores information in the first surface at the points of interaction that occur between the plurality of first magnetic impurities interacting with the flowing electrons to exchange, at each point of interaction, a nuclear spin of a respective first magnetic impurity with an electron spin of a respective flowing electron that has a first spin-momentum.

The TSS-3DTI 102 may include a plurality of surfaces, each with different spin-momentum locked charge carriers and a plurality of respective magnetic impurities.

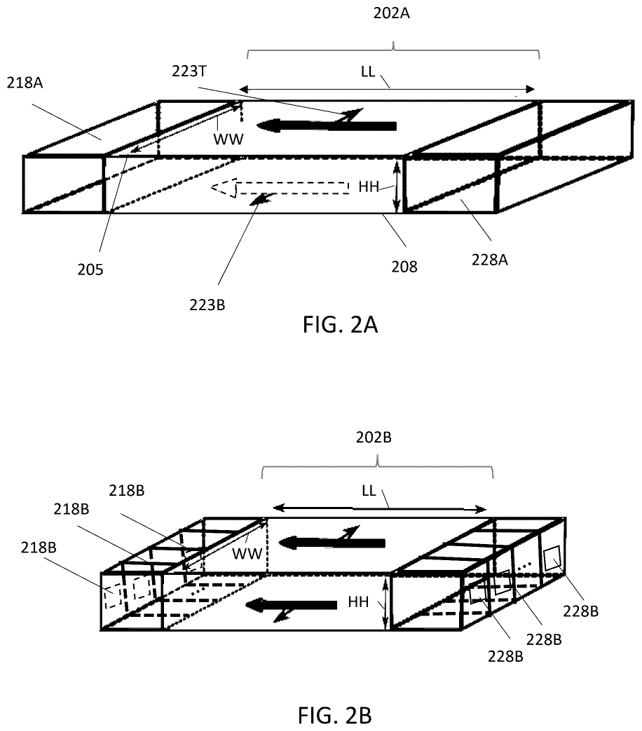

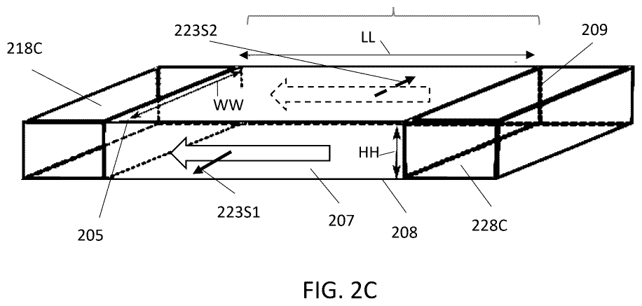

In FIG. 1, the system 100 may include a plurality of first contacts 118 are provided that are coupled to a first end of the TSS-3DTI 102. Each first contact 118 is a designated contact that is coupled to a respect energy source of a plurality of first energy sources 137, 147. The illustration shows two contacts and two energy sources in an energy source array 130. However, there can be 2-10 contacts and energy sources with a one-to-one correspondence, for example, to tune the quantum information engine. However, the system 100 may include one contact on an input side and one contact on the output side, as will be described in more detail in relation to FIG. 2A. The plurality of first contacts 118 are provided that are coupled to the at least one surface 105 of the TSS-3DTI 102.

The system 100 may include a plurality of second contacts 128 that are coupled to a second end of the TSS-3DTI 102. Each second contact 128 is coupled to a respect energy source 157, 167 of a plurality of second energy sources 157, 167. Any number of energy sources can be provided in the energy source array 150. However, there may be 2-10 contacts and energy sources with a one-to-one correspondence, for example.

The number of energy sources in array 130 and/or 150 may be 2-4, 4-10, or 10-50, for example. The limitations on the number of energy sources is based on the size of the device and application. In some examples, the number of energy sources in array 130 may be 2-6. However, the number of energy sources in the array 130 may be in the thousands.

Likewise, the number of energy sources in the energy source array 150 may be in the thousands. The number of energy sources in array 130 and array 150 do not need to be the same number of energy sources and can be even or odd numbers.

The system 100 may include one contact on an input side (i.e., the first end of the TSS-3DTI 102) and one contact on the output side (i.e., a second end of the TSS-3DTI 102). In some embodiments, the input side may be exchanged with the output side depending on the selected energy source in array 130 or 150.

The energy sources of array 130 may be coupled to supply energy from a single energy source to both a top surface 105 and bottom surface, shown in FIG. 2A, of the TSS-3DTI 102, simultaneously. The energy source array 150 may be coupled to supply energy from a single energy source to both a top surface 105 and bottom surface of the TSS-3DTI 102, simultaneously. A controller may select the energy sources from arrays 130 and 150.

The system 100 may include a tunable energy source array 130. The tunable energy source array 130 may include at least two reservoirs 137 and 147 electrically connected to one side of the TSS-3DTI 102 to supply a bias voltage across the TSS-3DTI 102 and to induce current along the top surface 105 of the TSS-3DTI 102. As will be discussed later, the TSS-3DTI 102 has a bottom surface electrically connected to the at least two reservoirs 137 and 147.

For purpose of illustration, a first and second reservoirs 137 and 147 can be electrically connected the surface 105 via contacts 118. Additionally, the first reservoir 137 initially can have one of a different temperature or a different chemical potential than the second reservoir 147.

The system 100 may include a tunable energy source array 150. The tunable energy source array 150 may include at least two reservoirs 157 and 167 electrically connected to the TSS-3DTI 102 to supply a bias voltage across the top surface 105 and to induce current along the surface. For purpose of illustration, a third reservoir 157 and a fourth reservoir 167 can be electrically connected to the top surface 105 of the TSS-3DTI 102. Additionally, the third reservoir 157 initially can have one of a different temperature or a different chemical potential than the fourth reservoir 167. As will be discussed later, the TSS-3DTI 102 has a bottom surface electrically connected to the at least two reservoirs 157 and 167.

In some embodiments, the tunable energy source array 130 may include only one energy source (i.e., reservoir) and the tunable energy source array 150 may include only one energy source (i.e., reservoir).

The system 100 may include a plurality of first tunable loads and/or sources 132 that have a first voltage potential range and a second plurality of tunable loads and/or sources 152 that have a second voltage potential range. The first voltage potential range is tuned to be one of higher and lower than the second voltage potential range to control the flow of the electrons to a respective contact of the plurality of first contacts 118 and the electrons to a respective contact of the plurality of second contacts 128.

In some embodiments, at least one of the first tunable loads and/or sources 132 may have a voltage potential which is lower than a voltage potential in the second voltage potential range. There is a one-to-one correspondence between the energy sources and the tunable loads.

FIG. 2A show a schematic diagram a TSS-3DTI 202A of FIG. 1 with two surfaces and metallic leads 218A and 218B. The effect of the nuclear spin polarization dynamics is demonstrated in a setup depicted in FIG. 2A, where two reservoirs (i.e., energy sources) would be connected to a TSS-3DTI 202A. In some embodiments, the TSS-3DTI 202A may store information in at least one of the surfaces selected from the group the top surface 205 and the bottom surface 208. However, for the sake of brevity, the explanation of FIG. 2A assumes the information storage of a first electron can take place in the top surface 205 and a second electron can take place in the bottom surface 208.

Now, focus only on the top surface 205 and assume that the top and bottom surface states do not hybridize. For the sake of demonstration, assume that the nuclear spin polarization density m has a weak position dependence and hence, only take its position independent contribution into account. Example cases are further described in relation to equations (1.59), (1.60), (1.61) and (1.62) below as it relates to the nuclear spin polarization density m.

The TSS-3DTI 202A includes a top (first) surface 205 with first spin-momentum locked charge carriers and a plurality of first magnetic impurities with a second average nuclear spin polarization to cause a spin flip of a first flowing electron (with a first spin-momentum) of the electrons at a first point of interaction on the top (first) surface 205 with a first magnetic impurity of the plurality of first magnetic impurities to exchange a nuclear spin of the first magnetic impurity with an electron spin of the first flowing electron to store information at the first point of interaction. The magnetic impurities will be described in more detail in relation to FIGS. 8A-8T.

The TSS-3DTI 202A includes a bottom (second) surface 208 with second spin-momentum locked charge carriers and a plurality of second magnetic impurities with a first average nuclear spin polarization. The TSS-3DTI 202A stores information in the bottom (second) surface 208 by causing a spin flip of a second flowing electron (with a second spin-momentum) at a second point of interaction on the second surface with a second magnetic impurity of the plurality of second magnetic impurities. This causes an exchange between a nuclear spin of the second magnetic impurity with an electron spin of the second electron to store information at the second point of interaction. The second surface 208 is doped with a plurality of second magnetic impurities with a second average nuclear spin polarization where an electron with the second spin momentum does not spin flip in response to an interaction with the second magnetic impurities with a second average nuclear spin polarization of the second surface.

The charge carriers for top and bottom surfaces 205 and 208 are oppositely polarized. The different surface polarizations are depicted in arrow 223T on the top surface 205 and arrow 223B on the bottom surface 208, where “T” denotes top and “B” denotes bottom.

The arrow 223T is intended to represent a “generally” or “on average” upward direction that would be essentially perpendicular to the top surface 205. The arrow 223B is intended to represent “a generally” or “on average” downward direction that would be essentially perpendicular to the bottom surface 208.

The TSS-3DTI 202A is configured to generally allow electrons to flow in a first direction, such as, without limitation, an x-direction or right to left. The TSS-3DTI 202A includes a top (first) surface 205 of first spin-momentum locked charge carriers and a plurality of first magnetic impurity with a second average nuclear spin polarization. The TSS-3DTI 202A includes a bottom (second) surface 208 of second spin-momentum locked charge carriers and a plurality of second magnetic impurity spins having a first nuclear spin polarization.

The interactions between the electrons with a first spin-momentum flowing on the top (first) surface 205 and the nuclear spin of any one first magnetic impurity causes a spin-flip and backscattering along the top (first) surface 205 relative to the first direction or x-direction. The interactions between those electrons with a second spin-momentum flowing on the bottom (second) surface 208 and the nuclear spin of any one second magnetic impurity cause a spin-flip and backscattering along the bottom (second) surface 208 relative to the first direction. The different average nuclear spin polarizations are depicted in arrow 223T on the top surface 205 and arrow 223B on the bottom surface 208. The x-direction is orthogonal to the y-direction.

FIG. 2B is similar to the embodiment of FIG. 2A. Thus, only the differences will be described. FIG. 2B shows a schematic diagram of a TSS-3DTI 202B of FIG. 1 and multiple contacts 218B and multiple contact 228B to connect to more than two reservoirs (i.e., energy sources). For example, each side of the TSS-3DTI 202B may have multiple energy sources and loads and/or sources. These contacts 218B and 228B are separated from each other, such as by isolation or spacing between each other. The flow of electrons, for example, may flow to a first surface in a single surface configuration, two surfaces for a two surface configuration, three surfaces for a three surface configuration or four surfaces for a four surface configuration.

In FIGS. 2A and 2B, the TSS-3DTI 202A, 202B have three-dimensional dimensions denoted as LL (length), WW (width) and HH (height).

FIG. 2C show a schematic diagram of a TSS-3DTI 202C of FIG. 1 with at least three surfaces and metallic leads 218C and 228C. The TSS-3DTI 202C may include multiple contact as shown in FIG. 2B. The TSS-3DTI 202C includes side surface 207 and 209. The side surface 207 and 209 are generally parallel to each other and perpendicular to top surface 205 and bottom surface 208. The side surfaces receive the flow of electrons.

The charge carriers for side surfaces 207 and 209 are polarized in the opposite directions. The different surface polarizations are depicted in arrow 223S1 on the side surface 207 and arrow 223S2 on the side surface 209, where “S1” denotes a first side and “S2” denotes a second side. The arrow 223S1 is intended to represent a “generally” or “on average” direction that would be essentially perpendicular to the side surface 207 but orthogonal to top and bottom surfaces 205, 208. The arrow 223S2 is intended to represent “a generally” or “on average” direction that would be essentially perpendicular to the side surface 209 but orthogonal to top and bottom surfaces 205, 208 and diametrically opposing the direction of arrow 223S1.

The configuration of the top surface and bottom surface of the TSS-3DTI 202C are essentially the same as the top surface and bottom surface of the TSS-3DTI 202B. Hence, no further discussion is necessary. The first average nuclear spin polarization and the second average nuclear spin polarization are generally diametrically opposing.

The side surface 207 (i.e., third surface) may include third spin-momentum locked charge carriers and a plurality of third magnetic impurities with a fourth average nuclear spin polarization to cause a spin flip of a third flowing electron (having a third spin-momentum) of the electrons at a third point of interaction on the side surface 207 with a third magnetic impurity of the plurality of third magnetic impurities to exchange a nuclear spin of the third magnetic impurity with an electron spin of the flowing electron to store information at the third point of interaction. The fourth average nuclear spin polarization is orthogonal to both the first and second average nuclear spin polarizations.

The side surface 209 (i.e., fourth surface) may include fourth spin-momentum locked charge carriers and a plurality of fourth magnetic impurities with a third average nuclear spin polarization to cause a spin flip of a fourth flowing electron (having a fourth spin-momentum) at a fourth point of interaction on the fourth surface with a fourth magnetic impurity of the plurality of fourth magnetic impurities to exchange a nuclear spin of the fourth magnetic impurity with an electron spin of the fourth electron to store information at the fourth point of interaction. An electron flowing along the third surface 207 does not flow along any of the other surfaces. Likewise, an electron flowing along the fourth surface 209 does not flow along any of the other surfaces.

The third average nuclear spin polarization is orthogonal to both the first and second average nuclear spin polarizations and generally diametrically opposing the fourth average nuclear spin polarization.

### Maxwell's Demon in a Three-Dimensional Topological Insulator: Disorder Effects

Three-dimensional topological insulators (3DTIs) described herein from the perspective of Maxwell's demon effect will now be described. TSS-3DTIs feature 2D surface states that exhibit spin-momentum locking, and for that reason, can be considered as a platform for Maxwell's demon implementations utilizing the hyperfine interaction between charge carriers and nuclear spins.

The description below includes an introduction to TSS-3DTIs and focus on the topologically protected surface states. The description also includes an investigation and study of the Maxwell's demon effect for TSS-3DTIs in the presence of nuclear spins. A discussion is provided below of the main differences between 2DTIs and TSS-3DTIs from the point of view of Maxwell's demon implementations. Then a description focused on the diffusive transport regime and the diffusion equation is obtained for the surface states interacting with both nuclear spins and nonmagnetic impurities.

### Topological Surface State Three-Dimensional Surface Topological Insulator (TSS-3DTI)

Following the discovery of QSHIs, the three-dimensional (3D) version of the time-reversal invariant TIs was predicted [3, 4]. Analogous to its 2D counterpart, TSS-3DTIs have a bulk band gap and conduct surface states, which are topologically protected by the time-reversal symmetry. The topological phases of a TSS-3DTI is described by four Z₂ invariants (v₀; v₁, v₂, v₃), where the invariant v₀ characterizes whether the TI is a strong TI (v₀=1) or a weak TI (v₀=0). The description below focuses on strong TIs where an in-depth discussion on topological phases of 3DTIs are described in [1]with respect also to suitable materials, which is incorporated herein by reference in its entirety.

The surface Fermi circle of a strong TI encloses an odd number of Dirac points. These 2D Dirac points are Kramers degeneracy points and the low-energy dynamics in the vicinity of these Dirac points are described by 2D Dirac Hamiltonian H given by equation (1.1) as:

$$H = ℏ {v}_{F} ( k \times σ ) \cdot \hat{z} , \qquad ( 1.1 )$$

where v_{F} is the Fermi velocity, where k=(kₓ, k_{y}) is the momentum, σ is the vector of Pauli matrices in electron spin space, x is the x-direction and y is in the y-direction. The Hamiltonian for the surface states given in equation (1.1) is almost identical to the graphene band structure, except for the fact that graphene contains at least four Dirac points (including spin and valley degrees of freedom), whereas a single surface state of a TSS-3DTI contains only one Dirac point. This is in violation with the Nielsen-Ninomiya theorem that states a single massless Dirac fermion cannot exist in a 2D lattice with time-reversal symmetry [5]. The resolution of this paradox is that there has to be another Dirac fermion residing on the opposite surface.

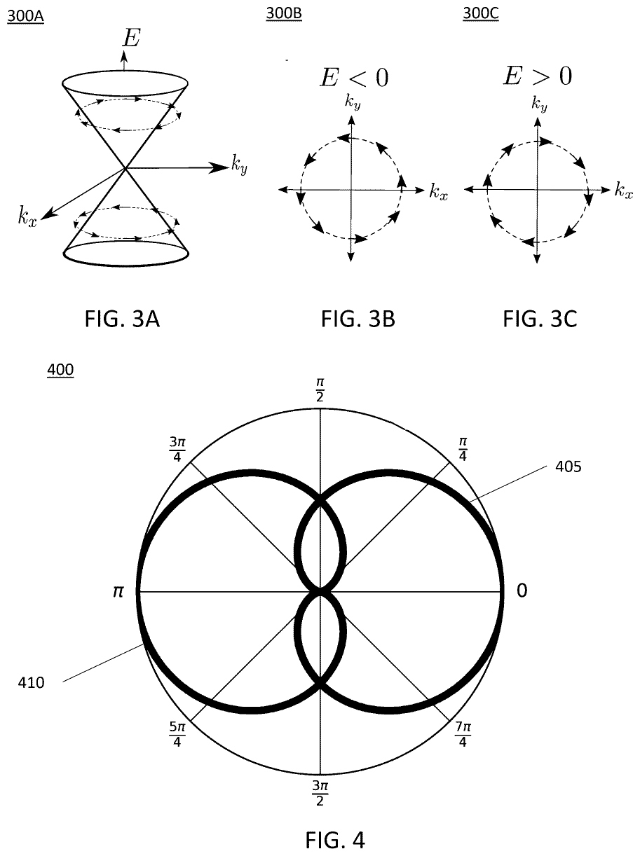

FIG. 3A illustrates a diagram 300A of the dispersion relation for the surface states of a TSS-3DTI. Here, the arrows represent the spin projection of the surface states, determined by the Hamiltonian given in equation (1.1). The sign of the spin chirality changes for the surface states with energy is shown in FIGS. 3B and 3C. FIG. 3B illustrates the sign of the spin chirality changes 300B for the surface states with energy E<0 below the Dirac point E=0, denoted by the arrows. FIG. 3C illustrates the sign of the spin chirality changes 300C for the surface states with energy above the Dirac point E=0, denoted by the arrows. In FIGS. 3A-3C, k=(kₓ, k_{y}) is the momentum, x is the x-direction and y is in the y-direction.

Another prominent feature of the surface states of a TSS-3DTI is the helical spin texture. In an ordinary 2D metal, every point on the Fermi circle contains both up and down spin states. However, the surface states of a TSS-3DTI do not have spin degeneracy; the time-reversal symmetry necessitates that states with opposite momenta k and −k have opposite spins. As a result, electrons acquire a w Berry phase while encircling the Fermi circle.

The immediate consequences of the w Berry phase is the absence of backscattering and consequently absence of localization for the surface states in the presence of disorder. Similar to helical edge states of the quantum spin Hall insulator phase, the surface states of TSS-3DTIs do not suffer from localization under any time-reversal invariant perturbation that does not cause bulk band gap to be closed. As typical for systems with spin-orbit coupling, this brings about weak antilocalization effects. On the other hand, the transport on the surface of a disordered TSS-3DTI is diffusive, whereas transport remains ballistic for quantum spin Hall insulators even in the presence of disorder.

### Maxwell's Demon Effect at the Surface of a TSS-3DTI

The feasibility of Maxwell's demon effect at the surface of TSS-3DTIs will now be described. Both the differences and similarities are identified of both 2DTIs and TSS-3DTIs, from the point of view of Maxwell's demon effect.

Both 2DTIs and TSS-3DTIs exhibit perfect spin-momentum locking, making them useful for Maxwell's demon implementations via spin-flip scattering with the nuclear spins and magnetic impurities. However, the main difference between the helical edge states of a quantum spin Hall insulator and surface states of a TSS-3DTI is the spin quantization axis; the helical edge states have a particular spin quantization axis, owing to one-dimensional (1D) nature of the edge states. However, electrons on the surface of TSS-3DTIs can propagate in any direction on the surface, resulting in no definite spin quantization axis [1, 3].

The effective Hamiltonian that describes the dynamics of the surface states of TSS-3DTIs is defined by equation (1.2) as:

$${H}_{0} = ℏ {v}_{F} ( k \cdot σ ) . \qquad ( 1.2 )$$

Note that for convenience, a rotation is performed in spin space to the Hamiltonian given in Equation (1.1) around spin-z axis, so that the spin and momentum points in the same direction. This choice of spin orientation does not change the physics of the problem.

In order to study the properties of the surface states of TSS-3DTI, first diagonalize the Hamiltonian for the surface states H₀ given in Equation (1.2) and obtain its eigenstates given by equation (1.3) as:

$${ψ}_{k \pm } ( x ) = \frac{1}{\sqrt{2}} ( \begin{matrix}1 \\ \pm {e}^{i θ}\end{matrix} ) \frac{{e}^{ik \cdot x}}{\sqrt{LL \times WW}} , \qquad ( 1.3 )$$

where 0=tan⁻¹ k_{y}/kₓ is the polar angle in the momentum space and LL and WW are the length and width of the system, as shown in FIG. 2A, respectively. Furthermore, ±represents the states with different helicity with energies E=±hv_{F}|k|. Without loss of generality, consider the case where the Fermi energy lies above the Dirac point and focus on+helicity eigenstate and drop the helicity sign for clarity. Note also that the angle θ uniquely specifies the spin orientation of the surface states for a given helicity, and for +helicity, then s=cos(θ) \hat{x}+sin(θ)ŷ.

Two sources of scattering are distinguished, namely the nonmagnetic impurity scattering, for which the term “disorder” refers, and nuclear spin and/or magnetic impurity scattering which may lead to spin-flip interaction. The uncorrelated disorder potential V(x) is assumed to obey [symbol] (V(x)V(x′) [symbol] =Dδ(x−x′), where D is the strength of the disorder. Next in order are the nuclear spins; the dominant source of interaction between the electrons and nuclear spins is the hyperfine Fermi contact interaction, given by equation (1.4) as:

$${H}_{h f} = \frac{λ}{2} {\sum }_{n} {I}^{n} \cdot σδ ( r - {r}_{n} ) \qquad ( 1.4 )$$

where the subscript hf is the hyperfine Fermi. Here, the factor ½ is for the nuclear spins and λ=A₀v₀/ξ is the hyperfine interaction strength, A₀ is the hyperfine coupling,

$${v}_{0} = {α}_{0}^{3}$$

is the unit cell volume, ξ is the surface state decay length in z-direction, Iₙ represents the Pauli spin matrices for the n^{th} nuclear spin at position xₙ=(xₙ, yₙ).

These two distinct sources of scattering mechanism are investigated and the resulting probability of elastic scattering is compared from an initial state k to a final state k′ on the Fermi circle. For scattering from single nonmagnetic impurity is given by equation (1.5) as:

$${P}_{nm} ( k , {k}^{′} ) = {cos}^{2} ( Δ θ / 2 ) , \qquad ( 1.5 )$$

where the subscript nm denotes the nonmagnetic impurity scattering and Δθ≡θ−θ′ is the scattering angle. On the other hand, a scattering process which changes the direction of a nuclear spin is given by equation (1.6) as:

$${P}_{sf} ( k , {k}^{′} ) = {sin}^{2} ( Δ θ / 2 ) , \qquad ( 1.6 )$$

where the subscript sf denotes the spin-flip scattering.

FIG. 4 illustrates the graphical representation 400 of the normalized scattering probability of the surface states as a function of the relative angle Δθ for process without spin-flip, denoted by curve 405 and with spin-flip denoted by curve 410. The normalized scattering probability for each case using a polar coordinate is shown in FIG. 4, where the distance from the origin is the probability of scattering. First and foremost, it is observed that for both nonmagnetic impurity scattering and scattering in which the initial and final states of the nuclear spins are known, which is simply called spin-flip scattering, the scattering probability is anisotropic, which is a manifestation of the nature of 2D Dirac fermions. The probability of backscattering for each case is distinguished; when the spin-flip scattering is not allowed (curve 405), backscattering probability (Δθ=π) vanishes, whereas for perturbations that allow spin-flip scattering (curve 410) have p_{sf}(Δθ=π)=1.

At first glance at equation (1.5) and equation (1.6), one can conclude that the surface states of TSS-3DTIs exhibit necessary ingredient for a Maxwell's demon implementation; that is the backscattering of the surface states is only possible via spin-flip scattering with the nuclear spins. This is an essential ingredient for the discharging (work extraction) phase of any Maxwell's demon implementation using the prescription. However, it is noticed that backscattering is also possible without spin-flip scattering in the diffusive regime.

For multiple scattering events from nonmagnetic impurities, the momentum and consequently the spin of the surface states are randomized. Therefore, the surface states suffer from backscattering due to nonmagnetic impurities for samples with length larger than the elastic mean free path [symbol] ₑ₁ set by the disorder strength.

In view of this additional backscattering mechanism, first consider the nuclear spins only, in order to get a glimpse of the Maxwell's demon effect in TSS-3DTIs. Also, ballistic samples are focused on with system size smaller than the elastic mean free path, where backscattering is expected to occur only via spin-flip with the nuclear spins. The effect can be investigated of the nuclear spins on the electron relaxation time by invoking the Fermi's Golden rule given by equation (1.7) as:

$${τ}_{k \to {k}^{′} ;}^{- 1} = \frac{2 π}{ℏ} \frac{{A}_{0}^{2} {v}_{0}^{2}}{4 {( LL \times WW )}^{2}} \frac{1}{{ξ}^{2}} \text{} {\sum }_{n} [ {sin}^{2} ( \frac{Δθ}{2} ) {δ}_{{m}_{n} , {m}_{n}^{′}} + \frac{1}{4} {δ}_{{m}_{n - 1} , {m}_{n}^{′}} + \frac{1}{4} {δ}_{{m}_{n + 1 ,} {m}_{n}^{′}} ] δ ( ℏ {v}_{F} ( k - {k}^{′} ) ) , \qquad ( 1.7 )$$

where mₙ and

$${m}_{n}^{′}$$

are the initial and final spin projections for the n^{th} nucleus, respectively. First consider the electron dynamics, such that the sum is performed over the possible nuclear spin configurations given by equation (1.8) as:

$${τ}_{k \to {k}^{′}}^{- 1} = \frac{2 π}{ℏ} \frac{{A}_{0}^{2} {v}_{0}^{2}}{4 {( LL \times WW )}^{2}} \frac{N}{{ξ}^{2}} [ {sin}^{2} ( Δ θ / 2 ) + \frac{1}{2} ] δ ( ℏ {v}_{F} ( k - {k}^{′} ) ) , \qquad ( 1.8 )$$

where N=N_{⬆}+N_{⬇}, is the total number of nuclear spins. Also, note that this scattering rate of the surface states from the nuclear spins includes both spin-flip scattering and the spin-conserving forward scattering. Therefore, the nuclear spins also lead to momentum relaxation via forward scattering.

Now focus on the dynamics of the nuclear spins in the absence of a voltage bias. Here the electronic distribution functions are taken into account and the rate of flips from nuclear spin-up to nuclear spin-down is obtained by equation (1.9) as:

$$\begin{matrix}{Γ}_{- +} = \frac{1}{8 π} \frac{{A}_{0}^{2} {v}_{0}^{2}}{{ξ}^{2}} \frac{1}{{( ℏ {v}_{F} )}^{4}} {N}_{↓} \int \frac{d E}{ℏ} {E}^{2} {f}_{+} ( E ) ( 1 - {f}_{-} ( E ) ) , \\ = \frac{1}{8 π ℏ} \frac{{A}_{0}^{2} {v}_{0}^{2}}{{( {ℏv}_{F} )}^{4} {ξ}^{2}} {N}_{↓} ( {E}_{F}^{2} + \frac{{π}^{2}}{3} {k}_{B}^{2} {T}^{2} ) {k}_{B} T ,\end{matrix} \qquad ( 1.9 )$$

where ƒ±is the electron distribution function with spin-up/down projected along the direction set by the propagation of the electrons in a two-terminal geometry in a quasi-1D system. Correspondingly, this choice of spin quantization-axis also determines the polarization direction of the nuclear spins. It should be noted that while deriving this rate of flipping, it is assumed that there only a single mode is occupied. Now consider the low temperature limit, E_{F}»k_{B}T, which is the experimentally relevant limit. Again, define a mean polarization and obtain the rate of change of mean polarization by equation (1.10) as:

$${Γ}_{- +} - {Γ}_{+ -} ≡ \frac{d m}{d t} = - 2 mN \frac{1}{8 πℏ} \frac{{α}_{0}^{2}}{{ξ}^{2}} {( \frac{{E}_{F}}{{E}_{B}} )}^{2} {( \frac{{A}_{0}}{{E}_{B}} )}^{2} {k}_{B} T \qquad ( 1.1 )$$

where an energy scale

$${E}_{B} = \frac{ℏ {v}_{F}}{{α}_{0}}$$

which roughly corresponds to the bulk band gap of the TSS-3DTI. Assume that no voltage bias is applied, hence equation (1.10) describes the depolarization process. The time scale of this process is inferred by equation (1.11) as:

$${τ}_{m}^{- 1} ≡ \frac{( {Γ}_{\pm } - {Γ}_{∓} )}{m N} = {γ}_{0}^{3 D} \frac{2 {k}_{B} T}{ℏ} , \qquad ( 1.11 )$$

where an effective interaction strength is defined as

$${γ}_{0}^{3 D} = \frac{1}{8 π} \frac{{α}_{0}^{2}}{{ξ}^{2}} {( \frac{{E}_{F}}{{E}_{B}} )}^{2} {( \frac{{A}_{0}}{{E}_{B}} )}^{2} .$$

It is indicated that, as compared to the time scale of mean polarization dynamics of its 2D counterpart, the rate of change of mean polarization dynamics of a TSS-3DTI contains an additional factor of (EF†E_{B})². It is noted that the case in which EF is in the band gap is considered. Therefore, if one also considers possible bulk thermal excitations which may eventually hinder the demon effect, it can be concluded that this factor can be substantially smaller than unity. This feature offers an explanation to long-retention times seen in experiments [2].

### Diffusive Regime

Above it was established that the surface states of a TSS-3DTI can be used to realize a Maxwell's demon implementation. However, as opposed to the quantum spin Hall insulators, the presence of nonmagnetic impurities at the surface of TSS-3DTIs leads to a diffusive transport regime which makes the analysis of Maxwell's demon more complicated.

Therefore, an extensive study of the impact of nonmagnetic impurity scattering on the Maxwell's demon effect is required. The diffusive limit of the 3DTIs (without the nuclear spins) and its transport properties have been studied in detail [6-8]. Below, the contribution of the disorder is investigated on the spin-charged coupled transport of electrons interacting with the nuclear spins, for TSS-3DTIs.

Start with the Hamiltonian of the overall system that is given by equation (1.12) as:

$$H ≡ {H}_{0} + {H}_{h f} + V ( x ) , \qquad ( 1.12 )$$

where H₀ describes the surface states of a TSS-3DTI (single surface) given by equation (1.1), H_{hf} is the hyperfine interaction between the electrons and the nuclear spins (equation (1.4)) and finally, V(x) describes the nonmagnetic impurity potential, specified by a random Gaussian disorder potential profile [symbol] (V(x)V(x′) [symbol] =n₀U²δ(x−x′) and zero mean value [symbol] (V(x) [symbol] =0. Here, U is the magnitude of the nonmagnetic impurity scattering strength and no is the nonmagnetic impurity density.

Employ the nonequilibrium Green's function formalism in order to describe the dynamics of the electrons interacting with both nuclear spins and nonmagnetic impurities. The usefulness of the nonequilibrium Green's function formalism resides in the fact that, the structure of the perturbation expansion is similar to the equilibrium theory, the only difference being the introduction of a contour. The diagrammatic formulation of the Keldysh technique is almost identical to the equilibrium diagrammatic formulation, except for the fact that the propagators and vertices contain contour indices [9].

In derivation for the transport equation for the electrons, the central quantity of interest is the electronic Keldysh space Green's function, which can be represented as a matrix in Keldysh space defined by equation (1.13) as:

$$\underline{G} ( 1 , {1}^{′} ) = [ \begin{matrix}{G}^{R} ( 1 , {1}^{′} ) & {G}^{K} ( 1 , {1}^{′} ) \\ 0 & {G}^{A} ( 1 , {1}^{′} )\end{matrix} ] , \qquad ( 1.13 )$$

where the abbreviation 1≡(x₁, t₁). Note that the matrix elements of the both the Green's function G are also matrices in spin space for the specific problem considered. The diagonal elements of G namely G^{R} and G^{A}, are the retarded and advanced Green's functions known from the equilibrium theory giving by equations (1.14) and (1.15) as:

$${{G}^{R} ( 1 , {1}^{′} )}_{σ , {σ}^{′}} = - i θ ( {t}_{1} - {t}_{{1}^{′}} ) 〈 \{ {ψ}_{σ} ( 1 ) , {ψ}_{{σ}^{′}}^{†} ( {1}^{′} ) \} 〉 , \qquad ( 1.14 )$$

$${{G}^{A} ( 1 , {1}^{′} )}_{σ , {σ}^{′}} = + i θ ( {t}_{{1}^{′}} - {t}_{1} ) 〈 \{ {ψ}_{σ} ( 1 ) , {ψ}_{{σ}^{′}}^{†} ( {1}^{′} ) \} 〉 , \qquad ( 1.15 )$$

where ψ_{σ} is the field operator for the electrons with spin σ and θ is the Heaviside function. Retarded and advanced Green's functions provide information about the available states, whereas the off-diagonal element of G, G^{K}, is the Keldysh Green's function which determines the occupation of the aforementioned states, which is defined by equation (1.16) as:

$${{G}^{K} ( 1 , {1}^{′} )}_{σ , {σ}^{′}} = - i 〈 [ {ψ}_{σ} ( 1 ) , {ψ}_{{σ}^{′}}^{†} ( {1}^{′} ) ] 〉 . \qquad ( 1.16 )$$

The effect of the nonmagnetic impurity scattering is introduced, as well as the effect of the nuclear spins, via a perturbation expansion for the Green's function given in equation (1.13). Similar to the equilibrium theory, the perturbation expansion via the Dyson equation is described, which enables the use of the concept of self-energy for constructing the Dyson equation. The self-energy in Keldysh formulation has the same triangular matrix structure as the Green's function given in equation (1.13), which is defined by equation (1.17) as:

$$\underline{\sum } ( 1 , {1}^{′} ) = [ \begin{matrix}{\sum }^{R} ( 1 , {1}^{′} ) & {\sum }^{K} ( 1 , {1}^{′} ) \\ 0 & {\sum }^{A} ( 1 , {1}^{′} )\end{matrix} ] , \qquad ( 1.17 )$$

where the Σ^{R(A)} is the retarded (advanced) self-energy, whereas Σ^{K} is the Keldysh self-energy. Each of these self-energy components are also matrices in spin space.

The benefit of the self-energy is that it allows for a clear way of constructing the Dyson equation. In the nonequilibrium theory, there are actually two Dyson equations (left and right Dyson equations) that contain complete information about the overall system. The derivation of the left and right Dyson equations is beyond the scope of this thesis.

Instead, the self-energy is calculated for each scattering mechanism (nonmagnetic impurity scattering and nuclear spin scattering) and the equation of motion is constructed by using the left-right subtracted Dyson equation within the gradient approximation given by equation (1.18) as:

$${\partial }_{t} \underline{G} + \frac{{v}_{F}}{2} \{ ( \hat{z} \times σ ) \cdot ∇ , \underline{G} \} + \frac{i}{ℏ} [ {H}_{0} + {\overline{H}}_{hf} , \underline{G} ] = - \frac{i}{ℏ} [ \underline{\sum } , \underline{G} ] , \qquad ( 1.18 )$$

where the term H̅_{hf} describes the average field generated by finite polarization of the nuclear spins, resulting in the precession of the electron spins. In the rest of the calculations, the precession of the electrons are ignored. The effects of both nonmagnetic impurity and nuclear spin scattering are manifested via the electron self-energy, which is decomposed as Σ+Σ₀+Σₘ.

In principle, the equation of motion for the G given in equation (1.18) contains the full information about the system. But the Keldysh component of the equation of motion given in equation (1.18) is of interest, as the Keldysh component yields the information about occupation of the states. Below, the Keldysh component of equation (1.18) obtained and a quasiclassical approximation is used in order to obtain the transport equations for spin and charge degrees of freedom.

### Quasiclassical Approximation

The quasiclassical approximation relies on the assumption that all the energy scales of the problem is small compared to the Fermi energy EF. Here, this assumption is used for the surface states of a TSS-3DTIs and the quasiclassical approximation is employed. The quasiclassical Green's function is defined by equation (1.19) as:

$$\underline{g} ( R , t , \hat{k} , ϵ ) = \frac{i}{π} \int d ξ \underline{G} ( R , t , k , ϵ ) , \qquad ( 1.19 )$$

where ξ=hv_{F}k−E_{F}. Note that the quasiclassical Green's function g is also a triangular matrix in Keldysh space with the same components (retarded, advanced and Keldysh) with each component being a matrix also in spin space. It is emphasized that the quasiclassical Green's function given in equation (1.19) depends on the direction of the momentum, which is denoted as k.

Within the quasiclassical approximation, the unperturbed retarded and advanced Green's functions are obtained for the surface state Hamiltonian H₀ given in equation (1.1) as equation (1.20):

$${g}^{\frac{R}{A}} = \frac{i}{π} \int d {ξ ( ϵ - ℏ {v}_{F} ( k \times σ ) \cdot \hat{z} + {E}_{F} \pm i {0}^{+} )}^{- 1} \approx \pm \frac{1}{2} ( 1 + ( \hat{k} \times \hat{z} ) \cdot σ ) . \qquad ( 1.2 )$$

Note that we regularize the divergent terms in the integral given above by assuming that Fermi energy scale is the largest energy scale in the problem. In this way, only consider the limit of small energies (|E| «hv_{F}k_{F}) with k_{F} being the Fermi wavevector) and obtain equation (1.20).

Now use equation (1.20) and the relation Σ^{R}=−Σ^{A} (as shown below this relation holds) in order to obtain the kinetic equation, i.e., the Keldysh component of the equation of motion given in equation (1.18) within quasiclassical approximation given by equation (1.21) as:

$${\partial }_{t} {g}^{K} + \frac{{v}_{F}}{2} \{ ( \hat{z} \times σ ) \cdot ∇ , {g}^{K} \} + i {v}_{F} {k}_{F} [ ( \hat{k} \times \hat{z} ) \cdot σ , {g}^{K} ] = - \frac{i}{ℏ} \{ {\sum }^{R} , {g}^{K} \} + \frac{i}{ℏ} {\sum }^{K} + \frac{i}{2 ℏ} \{ ( \hat{k} \times \hat{z} ) \cdot σ , {\sum }^{k} \} . \qquad ( 1.21 )$$

Note that equation (1.21) is generic for TSS-3DTIs without hexagonal warping and it is the central equation that is needed to solve in order to obtain the transport equation for the TSS-3DTIs.

To that end, first disregard the effect of the nuclear spins and obtain the self-energy due to nonmagnetic impurity scattering. Later, the effect of the nuclear spins are described and the transport equations are derived for the overall system, described by the Hamiltonian given in equation (1.12).

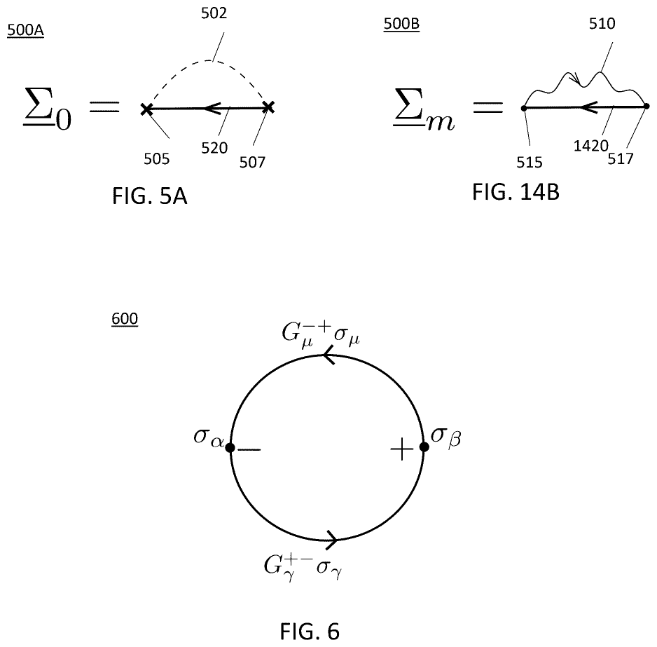

FIG. 5A illustrates a diagram 500A of the self-energy for the nonmagnetic impurity scattering. The dashed line 502 indicates the averaging over the positions of the impurities. FIG. 5B illustrates a diagram 500B of the self-energy for the nuclear spin scattering, where the wiggly line 510 is the nuclear spin correlators. The solid circles 515, 517 in FIG. 5B represent the nuclear spin scattering vertexes, whereas the crosses 505, 507 in FIG. 5A represents the nonmagnetic impurity scattering vertexes. In both FIGS. 5A and 5B, the solid line 520 represents the electronic Keldysh space Green's function.

### Nonmagnetic Impurity Scattering

In FIG. 5A, the self-energy diagram 500A for the nonmagnetic impurity scattering is shown. As Gaussian correlated nonmagnetic impurities are considered with zero mean value, one can easily evaluate the self-energy in Keldysh space denoted as Σ₀ is defined by equation (1.22) as:

$${\underline{\sum }}_{0} ( R , t , ϵ ) = {n}_{0} {U}^{2} \int \frac{{d}^{2} k}{{( 2 π )}^{2}} \underline{G} ( R , t , k , ϵ ) , \qquad ( 1.22 )$$

where the Wigner representation and center of mass time (t) and position (R) coordinates are used. Next, take the Fourier transform and represent the Green's function in energy(ϵ)—momentum(k) domain. Using the definition of the quasiparticle Green's function given in equation (1.19), the electron self-energy is re-expressed due to nonmagnetic impurity scattering defined by equation (1.23) as:

$${\underline{\sum }}_{0} = - \frac{i}{{τ}_{0}} 〈 \underline{g} 〉 , \qquad ( 1.23 )$$

where (g)≡∫d\hat{k}′/(2π) denotes the angular average over the Fermi circle. Moreover, τ₀ is the time scale related to this scattering mechanism is denoted by τ₀=(πv(E_{F})n₀U²)⁻¹, where

$$v ( {E}_{F} ) = \frac{{E}_{F}}{( 2 {πℏ}^{2} {v}_{F}^{2} )}$$

is the density of states at the Fermi energy. Note that the elastic mean free path associated with the nonmagnetic impurity scattering is [symbol] ₑ₁=V_{F}τ₀.

Each element of the self-energy matrix given in equation (1.23) is obtained by calculating the quasiclassical Green's function. By using the retarded/advanced quasiclassical Green's function given in equation (1.20), the retarded/advanced self-energy is obtained due to nonmagnetic impurity scattering given by equation (1.24) as:

$${\sum }_{0}^{R / A} = ∓ \frac{i}{2 {τ}_{0}} . \qquad ( 1.24 )$$

On the other hand, the Keldysh component of the self-energy matrix enters the kinetic equation as

$${\sum }_{0}^{K} = - i 〈 {g}^{K} 〉 / {τ}_{0} .$$

### Nuclear Spin Scattering

Next, focus on the electron self-energy arising from the interaction with the nuclear spins. Here, the diagram 500B of the self-energy due to nuclear spin scattering is shown in FIG. 5B. Even though the nuclear spins have no energetic dynamics similar to the case of nonmagnetic impurities, they still feature spin dynamics. Therefore, first the nuclear spins correlators need to be obtained, which can be defined by equation (1.25) as:

$${iD}_{α , β} ( 1 , 2 ) = 〈 {𝒯}_{c} ( {I}_{α}^{{n}_{1}} ( {t}_{1} ) {I}_{β}^{{n}_{2}} ( {t}_{2} ) ) 〉 , \qquad ( 1.25 )$$

where the same abbreviation 1=(t₁, x₁) is used as was used for electron Green's function. Here [symbol] denotes the contour ordering. Note that throughout the rest of the calculation, two-point correlators are considered for the nuclear spins only and the higher-order terms are ignored.

Then the contour ordered nuclear spin correlators are mapped given in equation (1.25) onto the Keldysh space and each element is found of the nuclear spin correlators defined by equations (1.26) and (1.27) as:

$${iD}_{αβ}^{\pm ∓} ( 1 , 2 ) = {δ}_{{n}_{1} , {n}_{2}} ( {δ}_{αβ} \pm i {ϵ}_{αβγ} {m}_{α}^{{n}_{1}} {m}_{β}^{{n}_{2}} ) , \qquad ( 1.26 )$$

$${iD}_{αβ}^{∓ ∓} ( 1 , 2 ) = {δ}_{{n}_{1} , {n}_{2}} ( {δ}_{αβ} \pm sign ( {t}_{1} - {t}_{2} ) i {ϵ}_{αβγ} {m}_{γ}^{{n}_{1}} - {m}_{α}^{{n}_{1}} {m}_{β}^{{n}_{2}} ) , \qquad ( 1.27 )$$

where

$${m}_{α}^{n} ≡ 〈 {I}_{α}^{n} 〉 .$$

Note that the position of the i^{th} nuclear spin is represented via nᵢ. In the rest of the calculations, only the on-site correlations are considered and a low nuclear spin density is assumed.

Next, the self-energy for electrons is calculated due to their interaction with the nuclear spins. If two-point correlators are considered for the nuclear spins only and the components are obtained of the self-energy matrix Σₘ as:

$${\sum }_{m}^{--} ( R , k , {t}_{1} , {t}_{2} ) = + i \frac{{λ}^{2}}{4} \int \frac{{d}^{2} {k}^{′}}{{( 2 π )}^{2}} {σ}_{α} {G}^{--} ( R , {k}^{′} , {t}_{1} , {t}_{2} ) {σ}_{β} {D}_{αβ}^{--} ( R , k - {k}^{′} , {t}_{1} , {t}_{2} ) , \qquad ( 1.28 )$$

$${\sum }_{m}^{++} ( R , k , {t}_{1} , {t}_{2} ) = + i \frac{{λ}^{2}}{4} \int \frac{{d}^{2} {k}^{′}}{{( 2 π )}^{2}} {σ}_{α} {G}^{++} ( R , {k}^{′} , {t}_{1} , {t}_{2} ) {σ}_{β} {D}_{αβ}^{++} ( R , k - {k}^{′} , {t}_{1} , {t}_{2} ) ,$$

$${\sum }_{m}^{- +} ( R , k , {t}_{1} , {t}_{2} ) = - i \frac{{λ}^{2}}{4} \int \frac{{d}^{2} {k}^{′}}{{( 2 π )}^{2}} {σ}_{α} {G}^{- +} ( R , {k}^{′} , {t}_{1} , {t}_{2} ) {σ}_{β} {D}_{αβ}^{+ -} ( R , k - {k}^{′} , {t}_{1} , {t}_{2} ) ,$$

$${\sum }_{m}^{+ -} ( R , k , {t}_{1} , {t}_{2} ) = - i \frac{{λ}^{2}}{4} \int \frac{{d}^{2} {k}^{′}}{{( 2 π )}^{2}} {σ}_{α} {G}^{+ -} ( R , {k}^{′} , {t}_{1} , {t}_{2} ) {σ}_{β} {D}_{αβ}^{- +} ( R , k - {k}^{′} , {t}_{1} , {t}_{2} ) .$$

Here, σᵢ are the Pauli matrices in spin space.

It is emphasized that the elements of the self-energy matrix given in equation (1.28) is written in a different basis than the one used in the description of the electronic Green's function. To that end, the retarded, advanced and Keldysh representation of the self-energy given in equation (1.28) is used. Starting with transforming the nuclear spin correlators given in equation (1.26) into retarded, advanced and Keldysh representation defines equations (1.29), (1.30) and (1.31) as:

$${iD}_{αβ}^{R} ( 1 , 2 ) = θ ( {t}_{1} - {t}_{2} ) 2 i {δ}_{{n}_{1} , {n}_{2}} {ϵ}_{αβγ} {m}_{γ}^{{n}_{1}} , \qquad ( 1.29 )$$

$${iD}_{αβ}^{A} ( 1 , 2 ) = - θ ( {t}_{2} - {t}_{1} ) 2 i {δ}_{{n}_{1} , {n}_{2}} {ϵ}_{αβγ} {m}_{γ}^{{n}_{1}} , \qquad ( 1.3 )$$

$${iD}_{αβ}^{K} ( 1 , 2 ) = 2 {δ}_{{n}_{1} , {n}_{2}} ( {δ}_{αβ} - {m}_{α}^{{n}_{1}} {m}_{β}^{{n}_{2}} ) . \qquad ( 1.31 )$$

For brevity, the matrix representation is used which is denoted as D, with a similar structure to the electron Green's function given in equation (1.13). Then all the elements of the self-energy given in equation (1.28) are transformed into retarded, advanced and Keldysh components. These are then found within the quasiclassical approximation to be defined by equations (1.32) and (1.33) as:

$${\sum }_{m}^{R / A} ( R , k , {t}_{1} , {t}_{2} ) = \frac{{λ}^{2}}{8} π v ( {E}_{F} ) \int \frac{d {\hat{k}}^{′}}{2 π} [ {σ}_{i} {g}^{K} ( R , {k}^{′} , {t}_{1} , {t}_{2} ) {σ}_{j} {D}_{ij}^{R / A} ( R , k - {k}^{′} , {t}_{1} , {t}_{2} ) + {σ}_{i} {g}^{R / A} ( R , {k}^{′} , {t}_{1} , {t}_{2} ) {σ}_{j} {D}_{ij}^{K} ( R , k - {k}^{′} , {t}_{1} , {t}_{2} ) ] , \qquad ( 1.32 )$$

$${\sum }_{m}^{K} ( R , k , {t}_{1} , {t}_{2} ) = \frac{{λ}^{2}}{8} π v ( {E}_{F} ) \int \frac{d {\hat{k}}^{′}}{2 π} [ {σ}_{i} {g}^{K} ( R , {k}^{′} , {t}_{1} , {t}_{2} ) {σ}_{j} {D}_{ij}^{K} ( R , k - {k}^{′} , {t}_{1} , {t}_{2} ) + {σ}_{i} ( {g}^{R} - {g}^{A} ) ( R , {k}^{′} , {t}_{1} , {t}_{2} ) {σ}_{j} ( {D}_{ij}^{R} - {D}_{ij}^{A} ) ( R , k - {k}^{′} , {t}_{1} , {t}_{2} ) ] , \qquad ( 1.33 )$$

where a mixed representation involving the center of mass coordinate R and momentum k is used, as well as the temporal coordinates t₁ and t₂. Now use the nuclear spin correlators given in equation (1.29), and obtain the explicit form of the self-energy defined by equations (1.34) and (1.35) as:

$${\sum }_{m}^{R / A} = \frac{ℏ}{{τ}_{sf}} [ {σ}_{i} 〈 {g}^{K} 〉 {σ}_{j} ( \pm θ ( \pm ( {t}_{1} - {t}_{2} ) ) {ϵ}_{ijk} {m}_{k} ) + {σ}_{i} 〈 {g}^{R / A} 〉 {σ}_{j} ( - i {δ}_{ij} ) ] , \qquad ( 1.34 )$$

$${\sum }_{m}^{K} = \frac{ℏ}{{τ}_{sf}} [ {σ}_{i} 〈 {g}^{K} 〉 {σ}_{j} ( - i {δ}_{ij} ) + {σ}_{i} ( 〈 {g}^{R} 〉 - 〈 {g}^{A} 〉 ) {σ}_{j} ( {ϵ}_{ijk} {m}_{k} ) ] , \qquad ( 1.35 )$$

where a timescale

$${τ}_{sf}^{- 1} ≡ \frac{{λ}^{2}}{4 ℏ} {n}_{m} π v ( {ϵ}_{F} )$$

associated with the mean nuclear spin polarization dynamics. Note that a coarse grained description is used of the local mean nuclear spin polarization, namely mₙ→m(R).

As the self-energy components given in equation (1.34) are matrices within the spin subspace, the quasiclassical Green's function is parametrize as g^{K}=g₀σ₀+g·σ. It is assumed that the nuclear spin correlators are independent of momentum and energy. Thus, equation (1.36) is obtained as:

$${\sum }_{m}^{R / A} = ∓ \frac{i ℏ}{{τ}_{sf}} [ \frac{3}{2} {σ}_{0} + 〈 g 〉 \cdot m {σ}_{0} - 〈 {g}_{0} 〉 m \cdot σ ] , \qquad ( 1.36 )$$

$${\sum }_{m}^{K} = - \frac{i ℏ}{{τ}_{sf}} [ 3 〈 {g}_{0} 〉 {σ}_{0} - 〈 g 〉 \cdot σ - 2 m \cdot σ ] ,$$

where [symbol] g^{R/A} [symbol] =±½. Note that arguments are omitted of the self-energy components, namely the position R, time T and energy ϵ. Furthermore, Σ^{R/A} contain terms that arise from the Fourier transformation with respect to the relative time coordinate η=t₁−t₂, which describe the nuclear spin mediated electron-electron interaction where the temporal coordinates are denoted as t₁ and t₂. The terms are ignored as their contribution is not significant compared to the electron dynamics.

The nonmagnetic impurity averaged self-energy given in equation (1.23) and the nuclear spin self-energy given in equation (1.36) allow us to determine the right hand side of equation (1.21), which are separated into two parts I₀=I₀[g]+Iₘ[g], which is given by equations (1.37) and (1.38), respectively as:

$${I}_{0} [ g ] = - \frac{1}{{τ}_{0}} [ g - 〈 g 〉 - \frac{1}{2} \{ ( \hat{k} \times \hat{z} ) \cdot σ , 〈 g 〉 \} ] . \qquad ( 1.37 )$$

$${I}_{m} [ g ] = \frac{3}{{τ}_{sf}} [ g - 〈 {g}_{0} 〉 {σ}_{0} + \frac{2}{3} 〈 g 〉 \cdot mg - \frac{2}{3} 〈 {g}_{0} 〉 m \cdot σ {g}_{0} - \frac{2}{3} 〈 {g}_{0} 〉 m \cdot g {σ}_{0} + \frac{1}{3} 〈 g 〉 \cdot σ + \frac{2}{3} m \cdot σ - 〈 {g}_{0} 〉 ( \hat{k} \times \hat{z} ) \cdot σ + \frac{1}{3} ( \hat{k} \times \hat{z} ) \cdot 〈 g 〉 {σ}_{0} + \frac{2}{3} m \cdot ( \hat{k} \times \hat{z} ) {σ}_{0} ] . \qquad ( 1.38 )$$

Now, insert equation (1.37) and equation (1.38) into equation (1.21) and consequently, the quantum kinetic equation is obtained, which is used to derive the transport equations for the surface states.

### Transport Equations for the Surface States

The form of the Hamiltonian for the surface states (equation (1.1)) suggests that the transport equations for the spin and charge degrees of freedom are coupled. As a first step in deriving the transport equations for the surface states, take the spin traces of equation (1.21). Then, starting with the σ₀ trace and obtain equation (1.39) as:

$${\partial }_{t} {g}_{0} + {v}_{F} \hat{k} \cdot ∇ {g}_{0} = - \frac{1}{{τ}_{0}} [ {g}_{0} - 〈 {g}_{0} 〉 + {( \hat{k} \times 〈 g 〉 )}_{z} ] - \frac{3}{{τ}_{sf}} [ {g}_{0} - 〈 {g}_{0} 〉 + \frac{1}{3} {( \hat{k} \times 〈 g 〉 )}_{z} + \frac{2}{3} m \cdot ( {g}_{0} 〈 g 〉 - 〈 {g}_{0} 〉 g + ( \hat{k} \times \hat{z} ) ) ] . \qquad ( 1.39 )$$

It is straightforward to obtain σ traces. Now focus on a nonequilibrium state such that g is diagonal in the eigenstates of H₀ [7]. In this case, only the states that are in the upper band contributes to g, hence at zeroth order g=g₀(\hat{k}×\hat{z}) with each element given by:

$${g}_{x} = {\hat{k}}_{y} {g}_{0} , and \qquad ( 1.4 )$$

$${g}_{y} = {\hat{k}}_{x} {g}_{0.} \qquad ( 1.41 )$$

At this point, assume that the nonmagnetic impurity scattering is the dominant source of scattering and ignore the contribution of the nuclear spins at first. In this case, equation (1.40) is used to obtain the subdominant term g_{z} defined by equation (1.42) as:

$${g}_{z} \approx \frac{1}{2 {v}_{F} {k}_{F}} ( \frac{{\hat{k}}_{x}}{{τ}_{0}} 〈 {\hat{k}}_{y} {g}_{0} 〉 - \frac{{\hat{k}}_{y}}{{τ}_{0}} 〈 {\hat{k}}_{x} {g}_{0} 〉 + {v}_{F} {\hat{k}}_{y} {∇}_{x} {g}_{0} - {v}_{F} {\hat{k}}_{x} {∇}_{y} {g}_{0} ) , \qquad ( 1.42 )$$

where the term g_{z} is seen as only nonzero for the first order in (k_{F} [symbol] ₑ₁)⁻¹. Note that a scenario is considered for which spin transport is not diffusive. Therefore, the first order corrections to equation (1.40) are not considered. Now insert this set of equations back into equation (1.39) and obtain equation (1.43) as:

$${\partial }_{t} {g}_{0} + {v}_{F} ∇ \cdot \hat{k} {g}_{0} = - \frac{1}{{τ}_{0}} [ {g}_{0} - 〈 {g}_{0} 〉 - \hat{k} \cdot 〈 {\hat{k}}^{′} {g}_{0} 〉 ] - \frac{3}{{τ}_{sf}} [ {g}_{0} - 〈 {g}_{0} 〉 + \frac{1}{3} \hat{k} \cdot 〈 {\hat{k}}^{′} {g}_{0} 〉 + \frac{2}{3} m \cdot ( {g}_{0} 〈 {g}_{0} ( {\hat{k}}^{′} \times \hat{z} ) 〉 - 〈 {g}_{0} 〉 {g}_{0} ( \hat{k} \times \hat{z} ) + ( \hat{k} \times \hat{z} ) ) ] . \qquad ( 1.43 )$$

This is the quantum kinetic equation for the charge sector of the surface states, interacting with both nonmagnetic impurities and nuclear spins. Then the angular average is taken over the quantum kinetic equation and the transport equation is obtained for the charge sector:

$${\partial }_{t} n + 2 {v}_{F} ( ∇ \times s ) \cdot \hat{z} = 0 , \qquad ( 1.44 )$$

and for the spin sector:

$${\partial }_{t} {s}_{x} + \frac{{v}_{F}}{4} {∇}_{y} n + \frac{{s}_{x}}{2 {τ}_{0}} = {Γ}_{x} , and \qquad ( 1.45 )$$

$${\partial }_{t} {s}_{y} + \frac{{v}_{F}}{4} {∇}_{x} n + \frac{{s}_{y}}{2 {τ}_{0}} = {Γ}_{y} , \qquad ( 1.46 )$$

where the generalized density matrix F(ϵ, R)=n(ϵ, R)/2σ₀ +s(ϵ, R)·σ, associated with the angular average of the quasiclassical Keldysh Green's function is used. Here, Γᵢ is defined as the nuclear spin contribution to the diffusion equation:

$${Γ}_{x} = - \frac{1}{{τ}_{sf}} [ {s}_{x} - {m}_{x} ( \frac{n}{2} ( 1 - \frac{n}{2} ) + {s}_{x}^{2} ) ] , \qquad ( 1.47 )$$

$${Γ}_{y} = - \frac{1}{{τ}_{sf}} [ {s}_{y} - {m}_{y} ( \frac{n}{2} ( 1 - \frac{n}{2} ) + {s}_{y}^{2} ) ] , \qquad ( 1.48 )$$

where the timescale 4τ_{sf}≡τ_{sf} is redefined. Note that in the absence of nuclear spin scattering, the terms Γᵢ vanish. In this case, the results obtained by Ref. [7]are recovered.

A case is explored where the transport is dominated by the nonmagnetic impurity scattering, τ₀«τ_{sf}. In this case, the transport is diffusive and the transport equations in this limit are solved. Then, focus on the quasistationary state (ωτ«1) and take the nonmagnetic impurity scattering as the dominant source of scattering. In the lowest order, equation (1.49) is obtained as:

$${s}_{x ( y )} = ∓ \frac{{v}_{F} {τ}_{0}}{2} {∇}_{y ( x )} n + 2 {τ}_{0} {Γ}_{x ( y )} . \qquad ( 1.49 )$$

The equation (1.49) is inserted into the continuity equation given in equation (1.44) and an energy resolved diffusion equation (1.50) is obtained as:

$${\partial }_{t} n - D {∇}^{2} n + 4 {ℓ}_{e 1} ( ∇ \times Γ ) \cdot \hat{z} = 0 , \qquad ( 1.5 )$$

where

$$D = {v}_{F}^{2} {τ}_{0}$$

as the diffusion constant [7]. The energy resolved particle current density is identified as j(ϵ, R)=−D∇n+4 [symbol] ₑ₁(\hat{z}×Γ). Complementary to the electron dynamics, the nuclear spin dynamics is obtained next and the term Γ is identified.

### Nuclear Spin Polarization Dynamics and Induced Current

Now obtain the dynamics of the nuclear spin polarization under the influence of nonequilibrium electron spin polarization and establish the connection between the source term Γ in equation (1.50).

First consider the nuclear spin self-energy, which is denoted as 529, which takes into account the effect of the electrons on the nuclear spins. Then, the nuclear spin self-energy Π is obtained as follows according to equation (1.51):

$${\prod }_{αβ}^{- +} ( 1 , 2 ) = - i \frac{{λ}^{2}}{4} Tr [ {σ}_{α} {G}^{- +} ( 1 , 2 ) {σ}_{β} {G}^{+ -} ( 2 , 1 ) ] , \qquad ( 1.51 )$$

where the trace is over the spin degree of freedom. Here, the lesser (greater) component is used of the electronic Green's function, namely G⁻⁺(G⁺⁻), for convenience.

In FIG. 6, a diagrammatic representation 600 of the lesser component of the nuclear spin self-energy

$${\prod }_{αβ}^{- +}$$

is illustrated. The Wigner representation for Π⁻⁺ is switched to and then Fourier transformation is applied with respect to the relative coordinates, to obtain equation (1.52) as:

$${\prod }_{αβ}^{- +} ( q , Ω ) = - \frac{{λ}^{2}}{4} \int \frac{{d}^{2} k}{{( 2 π )}^{2}} \int \frac{d ω}{2 π} Tr [ {σ}_{α} {G}^{- +} ( k , ω ) {σ}_{β} {G}^{+ -} ( k - q , ω - Ω ) ] . \qquad ( 1.52 )$$

Next, the electronic Green's function is parametrized, namely G≡G_{μ}σ_{μ} with p={0, x, y, z}and the lesser and greater components of the nuclear spin self-energy are calculated.

Next, focus on the quantum kinetic equation for the lesser components of the momentum integrated nuclear spin correlator,

$${d}_{αβ}^{- +}$$

as defined in equation (1.53) as:

$${d}_{αβ}^{- +} ( r , t ) = - \frac{i}{ℏ} ( {π}_{αδ}^{- +} {d}_{δβ}^{+ -} ( r , t ) - {π}_{αδ}^{+ -} {d}_{δβ}^{- +} ( r , t ) ) , \qquad ( 1.53 )$$

where the term on the right hand side describes the spin-flip interaction taking place between nuclear spins and electron spins. Here, π^{T±} describes the nuclear spin self-energy components, integrated over the momentum q. Then, the nuclear spin self-energy is inserted into equation (1.53) and the equation for the nuclear spin polarization dynamics is obtained. The x-component of the magnetization is then defined by equation (1.54) as:

$${\dot{m}}_{x} ( r , t ) = - \frac{{λ}^{2} {ϵ}_{F}^{2}}{4 {π ( ℏ {v}_{F} )}^{4}} \int \frac{d ϵ}{ℏ} {m}_{x} ( r ) ( \frac{n ( ϵ , r )}{2} ( 1 - \frac{n ( ϵ , r )}{2} ) + {s}_{x}^{2} ( ϵ , r ) ) - {s}_{x} ( ϵ , r ) , \qquad ( 1.54 )$$

where

$${d}_{αβ}^{- +} = {ϵ}_{αβγ} {m}_{γ} ( r )$$

(see equation (1.26)) is used for the case α≠β and consider a coarse grained description and define the average nuclear spin polarization m(r). Furthermore, the generalized density matrix F(ϵ, r)=n(ϵ, r)/2σ₀+s(E, r)·σ a is used. Similarly, the y-component of the magnetization is defined by equation (1.55) as:

$${\dot{m}}_{x} ( r , t ) = - \frac{{λ}^{2} {ϵ}_{F}^{2}}{4 {π ( ℏ {v}_{F} )}^{4}} \int \frac{d ϵ}{ℏ} {m}_{y} ( r ) ( \frac{n ( ϵ , r )}{2} ( 1 - \frac{n ( ϵ , r )}{2} ) + {s}_{y}^{2} ( ϵ , r ) ) - {s}_{y} ( ϵ , r ) , \qquad ( 1.55 )$$

It should be noted that the equations for the nuclear spin polarization dynamics given in equation (1.54) and equation (1.55) are generic for the Fermi contact interaction, whereas the density of states and the electron spin density vary depending on the electronic part of the Hamiltonian. To that end, incorporate the effect of the surface states of the TSS-3DTI via the electron density matrix and establish the connection between the nuclear spin dynamics and the source term Γ in the diffusion equation given in equation (1.50). Now, identify the integrand in the right hand side of equation (1.54) and equation (1.55) as the source term Γₓ and Γ_{z}, respectively. It is insightful to express the nuclear spin dynamics in a more compact form defined by equation (1.56) as:

$$\frac{dm}{dt} = - v \int d ϵΓ \qquad ( 1.56 )$$

where m(r)=nₘm(r) as the nuclear spin polarization density. Note that the energy integral of the source term Γ is related to the time rate of change of mean nuclear spin polarization density m. It is stressed that equation (1.56) is generic for the dynamics of nuclear spin polarization interacting with the electron spins via Fermi contact interaction, while the term Γ is specific for the system under consideration.

Now integrate equation (1.50) over energy and use equation (1.56) to obtain the diffusion equation for the charge density defined by equation (1.57) as:

$${\partial }_{t} ρ - D {∇}^{2} ρ + 2 e {ℓ}_{e 1} ∇ \cdot ( \frac{dm}{dt} \times \hat{z} ) = 0 , \qquad ( 1.57 )$$

where the charge density is defined as ρ≡−ev/2 ∫dϵ n+ve²ϕ where ϕ is the scalar electrostatic field. Then, find the charge current density from the diffusion equation given in equation (1.57) by equation (1.58) as:

$$J ( r , t ) = - D ∇ ρ + 2 e {ℓ}_{e 1} ( \frac{dm}{dt} \times \hat{z} ) , \qquad ( 1.58 )$$

where the time rate of change of the nuclear spin polarization density m is identified as a charge current source due to the spin-momentum locking feature of the surface states.

Regarding the TSS-3DTI of FIG. 1, first consider a case where a voltage bias is applied between the reservoirs, therefore, there is a charge current flowing in the x-direction. In this case, there is a one-dimensional (1D) diffusion equation, which is solved for and obtain the charge current as defined by equation (1.59) as:

$$I = GV - 2 eN \frac{{ℓ}_{e 1}}{LL} \frac{{dm}_{y}}{dt} , \qquad ( 1.59 )$$

where the relation I=J×WW is used, where J is the current density and WW is the surface state width. The first term on the right hand side represents the usual Ohm's law with conductance G=σW/L, where L is the surface state length and σ=e²vD is the conductivity given by the Einstein's relation (not to be confused with Pauli matrices in spin space), whereas the second term is the nuclear spin dynamics induced charge current. Here, N is the total number of nuclear spins at the surface of a TSS-3DTI and my is the average nuclear spin polarization in the y-direction.

The explicit form of the induced charge current due to nuclear spin dynamics is obtained by solving equation (1.55) under an applied voltage bias, which is defined by equation (1.60) as:

$$\frac{{dm}_{y}}{dt} = \frac{{γ}_{0}^{3 D}}{ℏ} ( \frac{{ℓ}_{e 1}}{LL} eV - {m}_{y} ( \frac{{ℓ}_{e 1}}{LL} eV coth ( \frac{{ℓ}_{e 1}}{LL} \frac{eV}{2 {k}_{B} T} ) ) ) , \qquad ( 1.6 )$$

where assumed nuclear spins are polarized in the y-direction only, for example. Now insert equation (1.60) into equation (1.59) and obtain the current-voltage characteristics of the TSS-3DTI in the presence of a Maxwell's demon memory defined by equation (1.61) as:

$$I = GV - 2 eN \frac{{ℓ}_{e 1}}{LL} \frac{{γ}_{0}^{3 D}}{ℏ} ( \frac{{ℓ}_{e 1}}{LL} eV - {m}_{y} ( \frac{{ℓ}_{e 1}}{LL} \frac{eV}{2 {k}_{B} T} ) ) , \qquad ( 1.61 )$$

where the effective interaction strength

$${γ}_{0}^{3 D} ≡ {λ}^{2} {v}^{2} / 4$$

as defined in equation (1.11). Next, focus on the work extraction phase. In the absence of an applied voltage bias, the first term in equation (1.59) vanishes. However, it is found that a finite nuclear spin polarization my induces a charge current according to the Maxwell's demon (MD) implementation defined by equation (1.62) as:

$${I}_{MD} = eN \frac{{ℓ}_{e 1}}{LL} \frac{{m}_{y}}{{τ}_{m}} \qquad ( 1.62 )$$

where the characteristic time scale τₘ is given in equation (1.11), entering the nuclear spin polarization induced charge current equation in the diffusive limit as well. The nonzero charge current due to finite nuclear spin polarization demonstrates that the Maxwell's demon effect is still valid in the diffusive regime. However, the magnitude of the Maxwell's demon induced current is scaled by the ratio of [symbol] ₑ₁/LL in the diffusive regime, as opposed to the quantum spin Hall insulator case. It should be stressed that this inefficiency is due to the randomization of the spin of the carriers due to nonmagnetic impurity scattering.

In conclusion, the TSS-3DTI described herein is from the perspective of quantum information engine implementation based on the interaction of spin-momentum locked charge carriers with the nuclear spins and/or magnetic impurity spins. As opposed to their 2D counterparts, the transport at the surface of TSS-3DTI can be diffusive for systems longer than the elastic mean free path [symbol] ₑ₁/LL. For that reason, the description above first focused only on the nuclear spins interacting with the spin-momentum locked surface states and established that TSS-3DTI can be used as platforms to realize Maxwell's demon implementation, similar to the quantum information engine based on a 2D topological insulator with 1D topological edge states [10]. On the other hand, in the diffusive limit, the momentum relaxation due to disorder is accompanied by the randomization of the spin of charge carriers due to the helical nature of the surface states, decreasing the efficiency of the conversion of the information entropy of the nuclear spin subsystem into electrical work. To that end, the effect of the disorder was investigated, caused by nonmagnetic impurity scattering, and obtained the quantum kinetic equation using Keldysh formalism and derived the diffusion equation for the electrons at the surface of a TSS-3DTI. Accordingly, it was found that the Maxwell's demon effect still survives for devices longer than the mean free path. However, as opposed to the ballistic case, the magnitude of the induced current (or similarly the induced voltage) is reduced by a factor of [symbol] ₑ₁/LL.

The storing entropy resulting from the above embodiments has distinct advantages over the conventional energy storage. There are no uncontrolled discharges and since the stored quantity is not energy, the limitations that apply to conventional energy storage does not apply, hence opening the gate to circuit elements that has higher energy/power densities. The current implementation also provides additional improvement over the existing coherence capacitor/quantum information engine (CC/QIE) entropy storage in that, for the usual CC/QIE, the efficiency is limited by the Joule heating resulting from the ballistic conduction of the helical edge states while there is no change in the nuclear spin polarization.

### Inductive Response of the QIE

The electronic theory of QIE in 1D builds on the theory by Bozkurt et al. to find the behavior of the QIE as a circuit element [10], which will be of use when formulating an expectation of the topological surface state, which is shown to be qualitatively similar in the previous section. The model applies to the QIE effect in 2D topological insulators having 1D edge states. How this would translate to a three-dimensional topological insulator is discussed later.

To find the total current through the QIE, focus on one edge of the material connected to charge reservoirs on its left and right side, with chemical potentials μ_{L} and μ_{R}. Applying a bias eV over the QIE shifts the chemical potential levels in the reservoirs as eV=μ_{L}-μ_{R}. The dynamics are studied in the short edge limit, which corresponds to neglecting any spatial dependence of the polarization and approximating the Fermi distributions of left- and right-moving electrons by their originating reservoir value. Furthermore, assume that the nuclear spins do not interact with each other.

Under these assumptions, the nuclear polarization process is governed by two scattering rates, given by equations (2.1) and (2.2) as:

$${ℏΓ}_{B} = ( {μ}_{L} - {μ}_{R} ) / 2 \qquad ( 2.1 )$$

$${ℏΓ}_{T} = ( {μ}_{L} - {μ}_{R} ) coth ( \frac{{μ}_{L} - {μ}_{R}}{2 {k}_{B} T} ) . \qquad ( 2.2 )$$

Γ_{B} contributes to a change in mean polarization from the biased current, whereas Γ_{T} corresponds to the thermal relaxation of the polarized nuclear spin system These scattering rates govern the time evolution of the mean polarization m given by equation (2.3)

$$\frac{dm}{dt} = {γ}_{0} {Γ}_{B} - m {γ}_{0} {Γ}_{T} . \qquad ( 2.3 )$$

Here, γ₀ denotes the hyperfine interaction strength, given by equation (2.4)

$${γ}_{0} = \frac{{λ}^{2}}{8 {πℏ}^{2} {v}_{F}^{2}} , with λ = \frac{{A}_{0} {v}_{0}}{S} , \qquad ( 2.4 )$$

where V_{F} is the Fermi velocity. The effective hyperfine coupling strength λ is dependent on the average hyperfine coupling energy A₀, unit cell volume v₀ and cross section S between helical edge states and nuclear spins.

The current per edge follows from the net distribution of moving charges in one direction ƒ±(ϵ) at energy ϵ given by equation (2.5) as:

$${I}_{QIE} = \frac{e}{h} \int ( {f}_{+} ( ϵ ) - {f}_{-} ( ϵ ) ) d ϵ = \frac{{e}^{2}}{h} V - eN \frac{dm}{dt} , \qquad ( 2.5 )$$

where e is an elementary electron charge, h is the Planck constant, V corresponds to voltage, N corresponds to the total amount of nuclear spins. As seen here, the total current consists of conventional ballistic conductance (with conductance quantum=e²/h) and a ‘demon-driven’ contribution. This gives the essence of the QIE: at zero applied external bias, the QIE can drive a nonzero current. Moreover, the QIE can drive a positive current against a small negative bias, allowing power to be dissipated from the QIE.

Equations (2.3) and (2.5) form the system of coupled differential equations governing the QIE dynamics, which will be discussed below.

### Isolated Device, Constant Bias

Assuming the applied bias (eV=μ_{L}-μ_{R}) is constant in time, the time evolution of the mean nuclear polarization m from equation (2.3) becomes equation (2.6)

$$m ( t ) = ( {m}_{0} - \overline{m} ) {e}^{- t / {τ}_{m}} + \overline{m} , \qquad ( 2.6 )$$

where m₀ is the initial polarization, m is the target polarization m and τₘ is the nuclear polarization timescale and where m and τₘ are given by equations (2.7) and (2.8)

$$\overline{m} ≡ \frac{{Γ}_{B}}{{Γ}_{T}} = \frac{1}{2} tanh ( \frac{{u}_{L} - {u}_{R}}{2 {k}_{B} T} ) \qquad ( 2.7 )$$

$${τ}_{m} = \frac{1}{{γ}_{0} {Γ}_{T}} . \qquad ( 2.8 )$$

Using equation (2.5), the total QIE current equation I_{QIE} is evaluated as equation (2.9):

$${I}_{QIE} = \frac{{e}^{2}}{h} V + eN {γ}_{0} {Γ}_{T} ( m ( t ) - \overline{m} ) = \frac{{e}^{2}}{h} V [ 1 + 2 π N {γ}_{0} ( m ( t ) coth ( \frac{eV}{2 {k}_{B} T} ) - \frac{1}{2} ) ] = \frac{{e}^{2}}{h} V [ 1 - \frac{ζ}{2} + m ( t ) ζcoth ( \frac{eV}{2 {k}_{B} T} ) ] , \qquad ( 2.9 )$$

where ζ=2πNγ₀ is dimensionless number resembling the interaction strength per edge.

### Low Voltage Limit, Frequency Response

For applications of the QIE, the response of the system under non-constant voltage is of importance. For low applied bias voltages (eV«k_{B}T) the approximations tanh(eV/k_{B}T)≈eV/k_{B}T and coth(eV/k_{B}T)≈k_{B}T/eV hold. This simplifies Γ_{T} ≈2k_{B}T/h and therefore given by equation (2.10):

$$\frac{dm}{dt} \approx \frac{{γ}_{0 e}}{2 ℏ} V - \frac{m}{{τ}_{m}} \qquad ( 2.1 )$$

where τₘ=h/2k_{B}Tγ₀ is the nuclear polarization timescale, independent of applied bias.

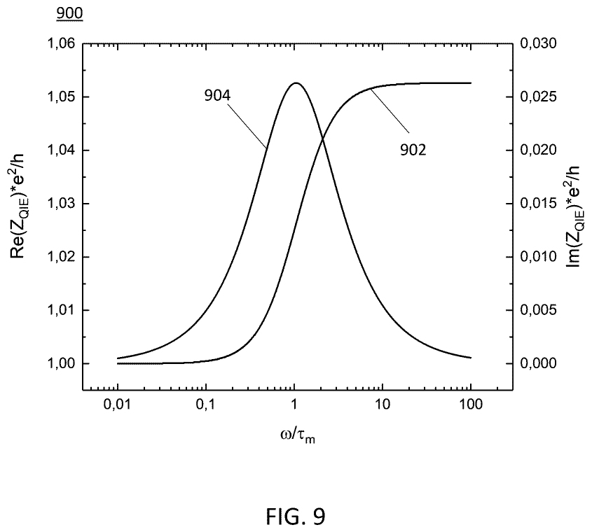

FIG. 9 illustrates a graph 900 of a frequency response of an isolated QIE, using ζ=0.1, in units of h/e². The real component of the impedance curve 902 is plotted according to measurement on the left axis of the graph 900. The imaginary part curve 904 is plotted according to the measurement on the right axis of the graph 900.

The frequency response of the QIE is uncovered by applying a harmonic external bias of the form V(ω)=V₀ exp(iωt), where V₀ is independent of ω and t. Then, the mean polarization is given by m(ω)=m₀(ω) exp(iωt) and equation (2.10) transforms into equations (2.11) and (2.12):

$$( i ω + \frac{1}{{τ}_{m}} ) m ( ω ) = \frac{{γ}_{0} e}{2 ℏ} V ( ω ) , \qquad ( 2.11 )$$

$$so that$$

$$I ( ω ) = \frac{{e}^{2}}{h} ( 1 - \frac{ζ}{2} \frac{i ω}{i ω + 1 / {τ}_{m}} ) V ( ω ) . \qquad ( 2.12 )$$

Equation (2.12) forms the basis of further analysis on the electronic response of the QIE, because it allows us to treat the QIE as a circuit element with a complex impedance. To analyze the response of the QIE in a circuit, the frequency-dependent complex impedance of the QIE is used, which is defined by equation (2.13) as

$${Z}_{Q} ( ω ) = \frac{V ( ω )}{I ( ω )} = \frac{h}{{e}^{2}} {( 1 - \frac{ζ}{2} \frac{i ω}{i ω - 1 / {τ}_{m}} )}^{- 1} . \qquad ( 2.13 )$$

This is plotted in FIG. 9, and shows an out-of-phase (imaginary) feature around τₘ, at which point the impedance of the device increases.

To obtain a general impression of the behavior of equation (2.12), the low- and high-frequency limits are studied. At low frequencies (ωτₘ«1), equation (2.12) simplifies to equation (2.14) as:

$$I ( ω ) = \frac{{e}^{2}}{h} ( 1 - \frac{ζ}{2} i {ωτ}_{m} ) V ( ω ) . \qquad ( 2.14 )$$

Recollecting the initial input V(ω)=V₀ exp(iωt), the phase difference between the current and voltage is found by equation (2.15):

$$I ( ω ) = \frac{{e}^{2}}{h} {V}_{0} exp ( i ( ω t - ϕ ) ) with ϕ = arctan ( \frac{{ζωτ}_{m}}{2} ) , \qquad ( 2.15 )$$

so, the voltage leads the current in phase, implying an inductive response. If ω>=0, the conductivity is purely ballistic, corresponding to the phase where the QIE is fully polarized and backscattering is prohibited.

In the high-frequency limit (ωτₘ»1), the frequency response becomes equation (2.16) as:

$$I ( ω ) = \frac{{e}^{2}}{h} [ 1 - \frac{ζ}{2} ( 1 + \frac{i}{{ωτ}_{m}} ) ] V ( ω ) , \qquad ( 2.16 )$$

which is again an inductive response, following from equation (2.17):

$$I ( ω ) = \frac{{e}^{2}}{h} {V}_{0} exp ( i ( ω t - ϕ ) ) with ϕ = arctan ( \frac{ζ / 2}{{ωτ}_{m} ( 1 - ζ / 2 )} ) . \qquad ( 2.17 )$$

When further increasing co, the phase difference between current and voltage disappears, rendering the behavior of the QIE purely resistive. This corresponds to the limit where switching the input voltage is too fast for a change in nuclear polarization to affect the conductivity.

### Low Voltage Limit, Time Response

The system of coupled differential equations formed by equations (2.3) and (2.5) allows for evaluating the time response of the system as well. First, the equations are dimensionalized in the low voltage limit to uncover the underlying dynamics and governing parameters. This results in equations (2.18) and (2.19) as:

$$\hat{V} ( \hat{t} ) - \frac{dm}{d \hat{t}} = \frac{{I}_{QIE}}{{I}_{0}} \qquad ( 2.18 )$$

$$\frac{dm}{d \hat{t}} + m ( \hat{t} ) = \frac{ζ}{2} \hat{V} ( \hat{t} ) , \qquad ( 2.19 )$$

using the definitions of equations (2.20) and (2.21):

$$\hat{V} = \frac{V}{{V}_{0}} , \hat{t} = t / {τ}_{m} \qquad ( 2.2 )$$

$$and$$

$${I}_{0} = \frac{eN}{{τ}_{m}} , and {V}_{0} = \frac{h}{{e}^{2}} {I}_{0} = \frac{ζ}{2} \frac{4 {k}_{B} T}{e} . \qquad ( 2.21 )$$

Here, V₀ sets the boundary on V for operating in the eV≈k_{B}T limit: this translates to \hat{V}«2/ζ, and must be taken into account when choosing an input voltage from which to evaluate the response. The behavior of equations (2.18) and (2.19) becomes apparent when investigating the situation of a polarized device under zero bias. A positive polarization (m >0) will decay to 0 whilst driving a positive current on a timescale of τₘ. Likewise, applying a positive bias voltage to the unpolarized QIE corresponds to a positive current. To simulate the time response of the QIE in-circuit in detail, I_{QIE} is coupled to the circuit using Kirchhoff's law.

From the steady state solution, the equilibrium polarization m̅ is obtained by equation (2.22) as:

$$\overline{m} = \frac{ζ}{2} \hat{V} = \frac{eV}{4 {k}_{B} T} . \qquad ( 2.22 )$$

This is consistent with equation (2.7) in the low voltage limit. Note that operating in this limit reduces the target polarization, and thereby the maximum amount of work that can be extracted from the QIE.

### Equivalent Circuit Modelling

The 1D model discussed above related to the expected results from measuring the QIE effect in topological surface states will now be discussed. The first part of the description addresses how the response of the QIE as a circuit element changes upon generalizing the effect to two dimensions, followed by an order-of-magnitude estimate of timescales governing a possible QIE response in BST films. For these calculations, the 1D QIE model will be used as an example. Then a deconstruction of the 1D QIE behavior into basic circuit elements is discussed, resulting in a scalable model that offers room for fitting measurement results while maintaining the qualitative features of a QIE.

References to the impedances of a resistor R, inductor L and capacitor C (Z_{R}, Z_{L} and Z_{C}, respectively) will be made in the description below. These impedances are given by equation (3.1) as:

$${Z}_{R} = R , {Z}_{L} = i ω L and {Z}_{C} = \frac{1}{i ω C} . \qquad ( 3.1 )$$

### From a QIE in 1D Edge States to 2D Surface States

When moving from 1D edge states to 2D surface states, the simplified view of the QIE operating along a short edge is no longer valid. The expected changes to the QIE operation are discussed upon changing from 1D to 2D surface states. Initially, an estimate of how diffusive transport reduces the current generated by a 2D QIE compared to the 1D model is described. This is followed by a first approximation of the 2D QIE as a grid of interconnected devices. Although this model is all but refined, it qualitatively provides insight into the expected response of a QIE in 2D surface states.

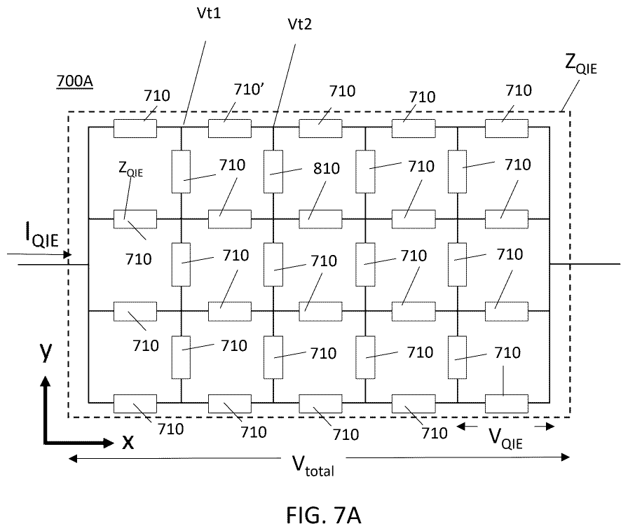

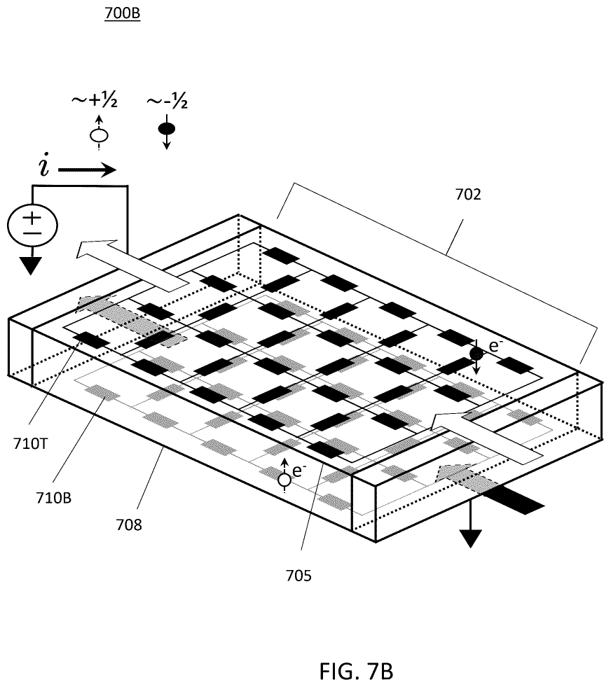

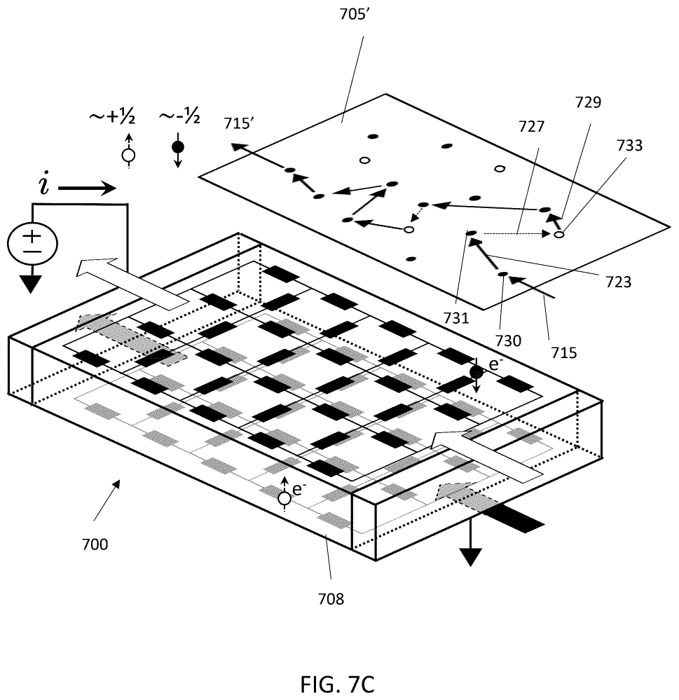

FIG. 7A illustrates a grid model circuit 700A used as first approximation of QIE operation in a 2D surface state. Each 1D element 710 on a vertex signifies a 1D QIE device with an impedance Z_{QIE}. By way of non-limiting example, 1D element 710′ is between vertex Vt1 and vertex Vt2. The 1D element 710′ is the second 1D element in the first row. The vertex Vt1 has a 1D element 710 coupled to it such that 1D elements 710 and 710′ are in series.

The vertex Vt1 has a 1D element 710 from the first column of 1D elements relative to the direction of current flow I_{QIE}. The vertex Vt2 has a third 1D element 710 coupled to it that such that 1D element 710′ and the third 1D element on the first row are in series. The vertex Vt2 has a 1D element 710 from the second column of 1D elements relative to the direction of current flow IQE.

The circuit 700A illustrates, by way of non-limiting example for illustrative purposes, 5 1D elements 710 in the x-direction which is parallel to the direction of the current I_{QIE}. The circuit 700 illustrates, by way of non-limiting example, 3 1D elements 710 in the y-direction for a Zₜₒₜₐₗ 5×3 grid model circuit 700. However, in practicality the number of 1D elements may be in the range of tens, thousands, tens of thousands, hundreds of thousand, millions or billions. The mesh on each surface can consist of many (up to millions) 1D elements in a grid configuration. It should be understood that the 1D elements may be infinitesimal in size and may not be generally counted.

The voltage across element is denoted as V_{QIE}. The total voltage denoted as Vₜₒₜₐₗ is denoted as across the Zₜₒₜₐₗ 5×3 grid model circuit 700. The diffusive surface state according to the Keldysh Green functions

$${I}_{MD} = - eN \frac{dm}{dt} \to {I}_{MD} = - eN \frac{l}{LL} \frac{dm}{dt}$$

where I/LL
denotes the ratio between mean free path (1) and device length (LL) and MD denotes a Maxwell's demon implementation. In this first approximation,

$${Z}_{total} = \frac{{n}_{x}}{{n}_{y}} {Z}_{QIE} \to {I}_{total} = \frac{{n}_{x}}{{n}_{y}} {( {Z}_{QIE} )}^{- 1} {V}_{total}$$

where nₓ denotes the number of elements 710 in the x-direction and n_{y} denotes the number of elements in the y-direction. Hence,

$${I}_{total} = \frac{{n}_{x}}{{n}_{y}} {( {Z}_{QIE} )}^{- 1} {n}_{x} {V}_{QIE} = {n}_{y} {I}_{QIE} . Also , \\ {I}_{total} = {n}_{y} {eN}_{QIE} \frac{dm}{dt} = \frac{1}{{n}_{x}} {eN}_{total} \frac{dm}{dt} = eN \frac{l}{LL} \frac{dm}{dt} .$$

In conclusion, the charging/discharging is

$$∼ \frac{eV}{{k}_{B} T} \frac{l}{LL} .$$

FIG. 7B illustrates a schematic diagram of a system 700B with a TSS-3DTI 702 (i.e., TSS-3DTI 102, 202A, or 202B) with a grid model circuit 700B of FIG. 7A on the top surface 705 and the bottom surface 708. The TSS-3DTI 702 of system 700B is similar to TSS-3DTI 202A so only the differences will be described in detail. In some embodiments, the system 700B includes one contact on an input side for both surfaces 705 and 708 and one contact on the output side for both surfaces. With respect to FIG. 2C, the TSS-3DTI 702 would include a grid model circuit 700B but to meet the dimensions of the side surfaces.

With respect to FIG. 7B, each surface (i.e., the top surface 205 and the bottom surface 208) maintains similar spin-polarized conductivity channels as with the 1D device 710T on the top surface 705 and ID device 710B on the bottom surface 708.

Furthermore, the spin-polarized conductivity on the top surface 205 is opposite the spin-polarized conductivity on the bottom surface 208 as described in relation to FIG. 2A. In operation, the electronic spin magnetic moments interact with nuclear spin polarization.

FIG. 7C illustrates electron flow along a first surface (i.e., top surface 705′) of the 3DS-TI 702 of FIG. 7B. The electron flow along the first surface is generally the same for all surfaces except for the interaction with the surfaces magnetic impurities. FIGS. 8A-8I illustrate electron interaction associated with the electron flow along a first surface of the system in FIG. 7C. FIG. 7C will be described together with FIGS. 8A-8I. It should be understood that electrons may flow in any direction. The representation of FIGS. 8A-8I is meant to represent one possible trajectory for an electron with a first spin-momentum along the first surface. Electrons may also collide with each other and other nonmagnetic impurity atoms. The description herein is not concerned with electron-to-electron collisions or electron-to-nonmagnetic impurity atoms, as the embodiments herein are for information storage via nuclear spin of magnetic impurity atoms. The description of FIGS. 8A-8T applies to all surfaces of the system used to store of information at points of interaction between any magnetic impurity with an opposite polarization associated with an incident electron flowing along the surface.

With respect to FIG. 8A, the first surface 705′ has a first spin-momentum locked charge carriers, denoted as the white surface, and a plurality of magnetic impurities, denoted as black circles and white circles. The magnetic impurities that are white circles having a second average nuclear spin polarization. This allows the first surface to store information at points of interaction that occur between the plurality of first magnetic impurities interacting with the flowing electrons to exchange, at each point of interaction, a nuclear spin of a respective first magnetic impurity with an electron spin of a respective flowing electron. As will be seen from the description of FIGS. 8A-8I, as nuclear spins change from the interactions with electrons, certain black circles may become white circles and vice versa.

In FIG. 8A only, the first surface 705′ is shown with dotted hatching. The dotted hatching denotes the presence of nonmagnetic impurities. The dotted hatching is removed in FIGS. 8B-8I to prevent overcrowding in the figures.

For the sake of illustration, electrons are configured to flow into the TSS-3DTI 702 in the direction of arrow 715, as shown in FIGS. 7C and 8A, and exit via arrow 715′, as also shown in FIGS. 7B and 8I, for example. The TSS-3DTI 702 may be configured to flow electrons in a different direction such as from arrow 715′ to 715.

For the sake of discussion, assume that the electrons flow in one direction, such as right to left on top surface 705′. In this illustration, the path or trajectory of an electron with approximately −½ electron spin is denoted as a black line. The first surface 705′ is configured to receive the electrons with the approximately −½ electron spin. The path of an electron with approximately +½ electron spin is denoted as a black dashed line, which occurs after a point of interaction due to an exchange between a nuclear spin and electron spin. The second surface 208 is configured to receive the electrons with the approximately +½ electron spin.

The solid black dot 730 on the top surface 705′ represents magnetic impurities having the same approximate electron spin of the black dashed line, which may cause regular scattering that causes the flow or trajectory of electrons (having the first spin-momentum) on the surface 705′ to generally trend from the right direction to left direction. The term “regular scattering” will sometimes be referred to as nonmagnetic scattering. The term “second average nuclear spin polarization” is used to denote that it is different or opposite the first spin-momentum of the electron spin to cause storage of information by a spin flip operation. The solid black dot corresponds to the plurality of first magnetic impurities with a first average nuclear spin polarization where an electron with the first spin momentum does not spin flip in response to an interaction with the first magnetic impurities with the first average nuclear spin polarization of the first surface.

The backscattering of the surface states is possible via spin-flip scattering with the nuclear spins of magnetic impurities assigned to a surface being opposite to the electron spin-momentum of the electron incident on the impurity. On the first surface, the magnetic impurities may have a second average nuclear spin polarization. On the second (bottom) surface, the magnetic impurities may have a first average nuclear spin polarization, for example.

In the illustration, the dot 731 represents a spin-flip scattering event between electron and a nuclear spin of a magnetic impurity (i.e., first magnetic impurity). This causes backscattering of an electron to travel in the direction of the dashed line arrow 727, in FIGS. 7C and 8C. The direction of arrow 727 is generally the reverse of the direction of electrons entering via arrow 715.

In the illustration, the position 730 corresponds to a regular scattering event and denoted as a black circle, caused by interactions of magnetic impurities at the point of interaction with a flowing electron. These magnetic impurities may exist in the first surface.

Because the arrow 723, in FIGS. 7C and 8B, is not directly parallel to the right-left direction, assume for the purposes of discussion, as electrons enter the TSS-3DTI along arrow 715, an electron undergoes a regular scattering event and the electron scattered by a regular scattering interaction continues along arrow 723 to another impurity along the surface.

With reference to FIG. 8B, an electron flowing in the direction or trajectory of arrow 723 interacts with magnetic impurity a position 731 which is also a point of interaction. The interaction causes a backscattering event at a point of interaction 731, denoted as a white circle, with magnetic impurities, shown in FIG. 8B. The backscattering event is where a spin-flip takes place at the point of interaction between the electron with a first spin-momentum and magnetic impurities with a second average nuclear spin polarization. This interaction exchanges (flips the spin) of both the electron previously traveling along solid arrow 723 and a nuclear spin at the point of interaction of position 731. This is represented as 1) a dashed arrow 727, as now shown on surface 705′ in FIGS. 8C; and 2) the exchange of the spin at position 731 is denoted by 731′ in FIG. 8C where the information to be stored in the nuclear spin in response to the interaction. For the sake of explanation, the spin-momentum of the electron flowing along the trajectory of arrow 723 has flipped. The spin flip is denoted by the different arrow types, as the original electron spin-momentum was according to the black line.

With respect to position 733 in FIG. 8C, the backscattered electron that follows a backscattering path along arrow 727 may produce another scattering event with a nuclear spin of the magnetic impurities of the surface 705′ such as at position 733. In this instance, position 733 has magnetic impurities denoted as a black circle. These magnetic impurities relative to the current spin-momentum of the electron cause a backscattering event at the point of interaction. With reference to FIG. 8D, the interactions between an electron from arrow 727 with a nuclear spin of magnetic impurities at position 733 cause an exchange of the nuclear spin at position 733 is denoted by 733′ in FIG. 8D where the information to be stored in the nuclear spin of the magnetic impurities in response to the interaction. This leads to FIG. 8D where the black circle of position 733 is changed to a white circle at the position denoted as 733′ where information is stored.

In FIG. 8D, after the interaction or exchange at position 733′, the electron's spin-momentum flips may follow a path or trajectory of arrow 729 denoted in a solid-black line. This is because, the 727 dashed arrow trajectory of the electron ends and electron proceeds along a new 729 black arrow in response to a backscattering event with respect to 733.

At the point of interaction at position 735 in FIG. 8E, the electron may interact at position 735 with a magnetic impurity which causes a regular scattering trajectory along path 739 to a position 741, denoted as a white circle.

In FIG. 8E, a spin flipping or backscattering event takes place to store information at position 741 denoted as 741′ in FIG. 8F. In FIG. 8F, the electron after the backscattering event travels along arrow 745 in a trajectory where the electron may interact with magnetic impurity at position 747, denoted as a black circle. Information is stored at position 747′ of FIG. 8G based on the exchange between the electron traveling along the dashed black line and the magnetic impurity 747, of FIG. 8F.

In FIG. 8G, in response to the spin-flip exchange and information storage, the black circle changes to a white circle at position 747′. In FIGS. 8G and 8H, the interaction at position 747′ results in a backscattering event where the electron's spin-momentum flips and is scattered in a trajectory denoted by the black arrow 749. At FIG. 81, the electron leaves the surface. The electron may continue to interact with other impurities (black circles or white circles in the same fashion described earlier) until it leaves the first surface denoted by arrow 715′.

In view of the foregoing, backscattering events may occur when an electron's spin of an electron flowing along a surface of the TSS-3DTI exchanges spin with the nuclear spin of magnetic impurities having an average nuclear spin polarization that is in a different direction/polarization than the electron. In view of the explanation above, the spin-flipping operation causes the second average nuclear spin polarization of a particular one magnetic impurity on the surface to exchange an amount of spin with the electron spin of an incident electron at the point of interaction. This causes the spin-momentum of the electron to flip and the nuclear spin of the magnetic impurity. The electron may undergo multiple spin-momentum flips as its trajectory interacts with those the magnetic impurities of the first surface along the trajectory. The nuclear spin of the magnetic impurities may flip as it interacts with an incident electron based on the electrons current spin-momentum.

The grid of 1D elements on the top and bottom surfaces of FIG. 7C represents the multiple directions in which the electron can travel, as a first approximation for the topological surface state.

### Estimated Effect of Diffusive Transport

First of all, the devices that will be measured experimentally show diffusive transport on the top and bottom surfaces, instead of ballistic transport along the device edges. This is due to the device length typically being much larger than the mean free path. This renders the assumption of operating on a short edge invalid: the chemical potential will drop over the length of the device, instead of left- and right-movers attaining the value of their originating reservoir.

To estimate the order of magnitude of the QIE effect in a 2D surface state, the typical current generated can be expressed by as equation (3.2):

$${I}_{0} ∝ \frac{eN}{{τ}_{m}} \frac{l}{LL} \qquad ( 3.2 )$$

The 2D character of the surface states is captured in l/LL, which denotes the ratio between mean free path (l) and device length (LL): although direct backscattering is forbidden without breaking time-reversal symmetry, an electron can reverse direction by coupling to multiple nonmagnetic scattering centers in series. Consequently, the spin battery effect is attenuated in diffusive materials. 2D QIE as a Grid of 1D Devices

Another way of visualizing the diffusive behavior is modeling the 2D QIE as a grid of interconnected 1D QIE devices, with individual length of the order of the mean free path. As each device operates as a function of the voltage drop over the corresponding vertex, the simplest assumption is that spin is not conserved at each node, and that the transmission probability into each vertex is equal. Then, each separate vertex can be replaced by a QIE device. An example circuit is shown in FIG. 7A.

Each separate device operates as a function of the voltage drop over the corresponding vertex. Recalling that the equation describing the QIE as a circuit element is derived in the low voltage limit (equation (2.12) above), this limit needs to hold per vertex.

Therefore, the average voltage drop over the mean free path is considered. As the mean free path in diffusive surface states is much smaller than the device length, the voltage drop over a single mean free path is much lower than the total voltage drop over the device. Therefore, typically the low voltage limit would suffice, and equation (2.12) can be used to define the separate circuit elements.

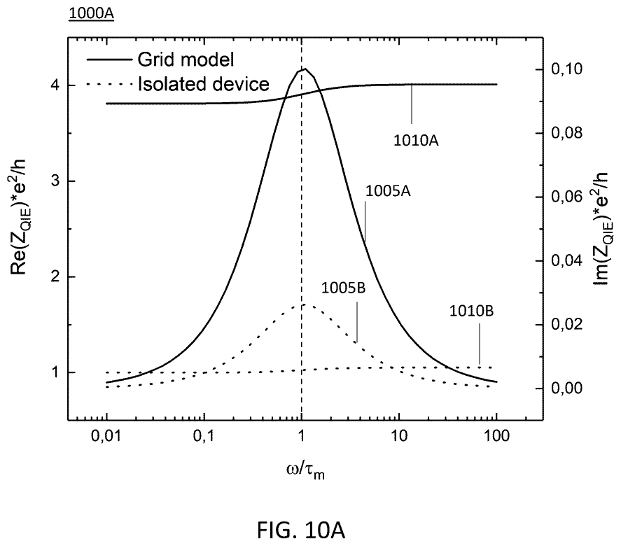

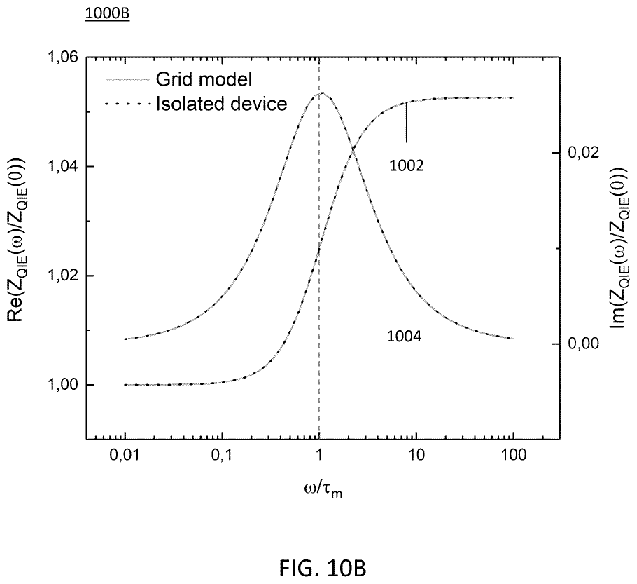

FIGS. 10A and 10B illustrate graphical representations of real and complex impedance of an 80×20 QIE grid compared to a single QIE device. FIG. 10A illustrates a graph 1000A of Z_{QIE} normalized by h/e², corresponding to ballistic conductance, where the right axis plots the imaginary impedance of Z_{QIE} denoted by curves 1005A and 1005B and the left axis plots the real impedance of Z_{QIE} denoted by curve 1010A and 1010B. Curve 1005A is the imaginary impedance Z_{QIE} for a grid model. Curve 1005B is the imaginary impedance Z_{QIE} for an isolated device. Curve 1010A is the real impedance Z_{QIE} for a grid model. Curve 1005B is the real impedance Z_{QIE} for an isolated device.

FIG. 10B illustrates a graph 1000B of Z_{QIE} normalized by its low-frequency value, showing overlapping results for the grid and isolated device, where the right axis plots the imaginary impedance of Z_{QIE} represented by curve 1004 and the left axis plots the real impedance of Z_{QIE} represented by curve 1002.

Assuming the voltage is distributed homogeneously at the left and right sides of the device, the equivalent impedance of the QIE grid is calculated. The system is solved by means of mesh current analysis, where a system of equations is obtained by balancing the voltage drops in each individual loop in the circuit.

The graph 1000A of FIG. 10A shows the results, denoted by line 1005, of an example calculation using a grid of 80 devices (i.e., elements 710 of FIG. 7A) in the x-direction (parallel to the current injection) and 20 devices (i.e., elements 710 of FIG. 7A) in the y-direction. Comparing this to an isolated QIE, denoted as dotted line 1010, an inductive feature is present at the same timescale, although the magnitude is different. Each device has an impedance Z_{QIE}.

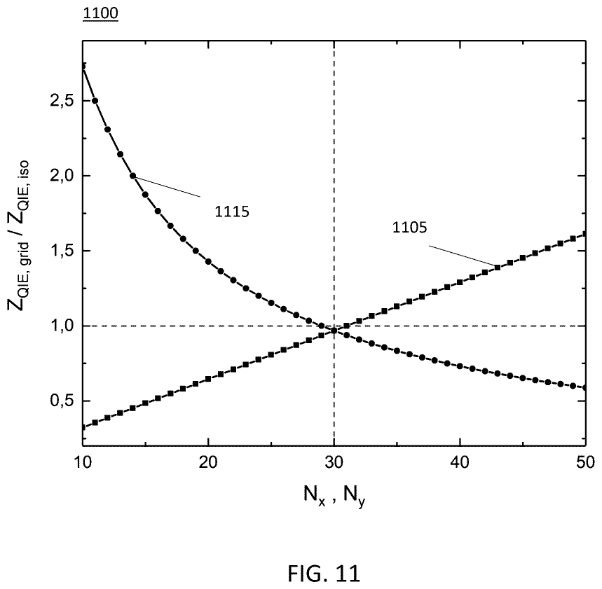

The graph 1000B of FIG. 10B shows that the effective impedance of the grid model of FIG. 7A is merely a rescaled response of a single QIE. All devices in the grid have an equal single-QIE response. Varying the Nₓ×N_{y} grid size results in FIG. 11, where the scaling factor between the grid and isolated device, denoted in dotted curve, impedance is shown, where x is the number of 1D elements in the x-direction and y is the number of 1D elements in the y-direction. The scaling factor is linearly dependent on Nₓ and inversely proportional to N_{y}, as expected when considering expansion of the grid as adding multiple series or parallel circuit elements. This implies that a QIE effect would be enhanced by increasing the length-to-width ratio of the topological surface state.

Upscaling the grid model to more realistic topological insulator dimensions, where the vertex length corresponds to the mean free path, would require values of Nₓ and N_{y} much larger than used in herein. For example, the typical mean free path 1˜10 nm in a 10 μm×400 μm device corresponds to a 1000×40000 grid, becoming computationally heavy.

In the currently used grid model, this would not give much additional information on behavior of the device, as the response remains proportional to the 1D QIE.

The considerations here show that the 1D effect can be a qualitatively reasonable expectation for QIE behavior in a 2D surface state, as the response from a preliminary 2D model is seen as a scaled version of the 1D model, where the characteristic timescale is not influenced. However, more refined modeling is required for quantitative results.

Therefore, in the following discussions the 1D theory will be used as a qualitative basis for evaluating the interplay between the QIE and other (stray) circuit components in the measurement circuit.

FIG. 11 illustrates a graph 1100 of the effect of varying the QIE grid size (Nₓ×N_{y}) on the scaling factor between the grid impedance and single device impedance. Varying Nₓ while N_{y}=30 results in the line curve 1105, whereas the line curve 1115 is obtained by setting Nₓ=30 while N_{y} varies.

### Estimation of Nuclear Polarization Timescale

In approximating the 2D QIE as a grid of 1D devices, the characteristic timescale associated with the QIE is observed as independent of device dimensions, and equal to the 1D model. Based on material properties and the 1D theory, the expected timescale corresponding to 1D edge states in BST can be refined. This will provide an order-of-magnitude estimate of the measured timescales in the QIE experiments.

The calculation for BST is performed following the method by Joris Voerman in BSTS flakes [11]. Similar to BSTS where BSTS is Bi₂₋ₓSbₓTe_{3-y}Se_{y}, where x indicates the relative Sb content and y the Se content in BST the bismuth will dominate spin orbit coupling and hyperfine interaction as it is the heaviest element, with an average hyperfine interaction strength of 62 μeV [11]. Bi is Bismuth; Sb is antimony; Te is Tellurium; and Se is Selenium.

BST follows the crystal structure of the binary compound Bi₂Te, with a unit cell volume of 0.5 nm³ [12]. From angle-resolved photoemission spectroscopy (ARPES) measurements on BST, the Fermi velocity is determined to be ˜3.6 10′ m/s [13]. For a 1D QIE effect in an edge state of radius 1 nm, equation (2.4) gives equation (3.3) as:

$$λ = \frac{{A}_{0} {v}_{0}}{S} ∼ 7.9 \cdot {10}^{- 34} Jm \qquad ( 3.3 )$$

$$and$$

$${γ}_{0} = \frac{{λ}^{2}}{8 {πℏ}^{2} {v}_{F}^{2}} ∼ 1.7 \cdot {10}^{- 11}$$

As above, the device will most likely operate in the low voltage limit as the voltage drop over the mean free path would be small. In this limit, τₘ=h/2k_{B}Tγ₀, so at T=300 K the characteristic QIE timescale is given by equation (3.4)

$${τ}_{m} = \frac{ℏ}{2 {k}_{B} T {γ}_{0}} ∼ 0.7 ms . \qquad ( 3.4 )$$

This rough estimate of τₘ provides an indication in which range the measurements will need to be performed. The exact dependence of τₘ on temperature can be discussed. The above equation suggests that for higher temperatures the magnitude of the driven current increases, albeit decaying on a shorter timescale. This will hold until k_{B}T becomes comparable to the band gap and thermally excited bulk states are able to contribute to transport, creating a shunt that reduces the magnitude of the QIE effect.

On the other hand, the dimensionless electron-spin nuclear-spin interaction strength γ₀ can change as a function of temperature as well. Increasing temperature, for instance, causes a broader range of states (˜k_{B}T) to contribute. As states with energy located further away from the Dirac point become less localized, X and therefore γ₀ will decrease through the increasing cross section S. This would increase τₘ in turn, and decrease the typical current I₀. On the other hand, more, more nuclei will in total interact with spin polarized charges, which would then increase I₀. How strong these effects manifest themselves depend on the exact energy dispersion of the material.

Another reason that could lead to a changed value of τₘ compared to the 1D model is found by considering spin relaxation and decoherence timescales. Generally, equilibration of a spin bath is described using two timescales: τ₁ and τ₂, where typically τ₁ >τ₂ [14, 15]. Ti is the longitudinal relaxation time, or characteristic time it takes for the net magnetization of a spin bath to reach zero. The decoherence time τ₂ signifies the transverse relaxation time, or the elapsed time before an ensemble of spins has lost its phase information due to fluctuations in individual precessing frequencies. Charging and discharging of the 1D QIE is governed by Ti, because the edge states strictly consist of spin-up or down carriers. Due to the multiple scattering directions being available in the 2D QIE, combined with the diffusive behavior of the material, a transverse loss of spin information will affect the average direction in which a discharging current is driven. Therefore, τ₂ could dominate the 2D QIE dynamics.

### Inductive Equivalent to QIE

The 1D model was used to obtain an impression of how the stray circuit elements and the QIE could interfere. The description below will focus on defining an equivalent circuit for the QIE itself, which results in a scalable model that is qualitatively equal to the 1D response. Based on the considerations above, this will give a first approximation for comparing measured results to theoretical expectations. The equivalent circuit will use resistors, inductors and capacitors as building blocks. Non-ideal behavior can then be incorporated by scaling the individual circuit components. This will be used to fit measured data in the frequency- and time response, defined in above.

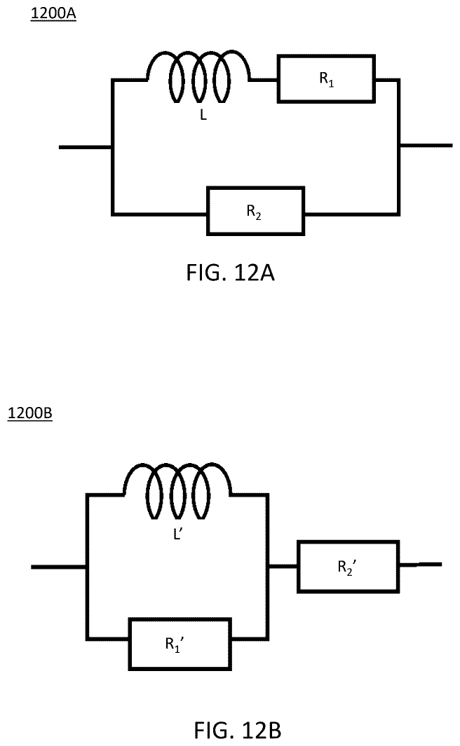

FIG. 12A illustrates an equivalent configurations of LRR-circuits 1200A, with frequency response equal to the QIE in a parallel configuration. FIG. 12B illustrates an equivalent configurations of LRR-circuits 1200B, with frequency response equal to the QIE in a series configuration.

The current-to-voltage relationship of the QIE is given by equation (2.12) above. A similar frequency response can be obtained using a combination of one inductor and resistor parallel to a second resistor (parallel LRR model, FIG. 12A, resulting in equation (3.5) as:

$${I}_{LRR , par} ( ω ) = ( \frac{1}{i ω L + {R}_{1}} + \frac{1}{{R}_{2}} ) V ( ω ) . \qquad ( 3.5 )$$

This is equivalent to the QIE under the conditions defined by equation (3.6)

$${( {R}_{1} )}^{- 1} ↔ \frac{{e}^{2}}{h} \frac{ζ}{2} \qquad ( 3.6 )$$

$${( {R}_{2} )}^{- 1} ↔ \frac{{e}^{2}}{h} ( 1 - \frac{ζ}{2} ) and$$

$$L ↔ \frac{h}{{e}^{2}} \frac{2}{ζ} {τ}_{m}$$

The fact that I_{LRR,par}(ω) matches I_{QIE}(ω) does not imply that this is the only equivalent circuit possible. A three element circuit has two nontrivial configurations [16], of which the second combination equivalent to the QIE consists of a parallel inductor and resistor combination, in series with a second resistor (series LRR model, FIG. 12B).

The transformation between the two equivalent circuits corresponds to substituting according to equation (3.7)

$${R}_{1}^{′} ↔ \frac{{R}_{2}}{{R}_{1} + {R}_{2}} {R}_{2} \qquad ( 3.7 )$$

$${R}_{2}^{′} ↔ \frac{{R}_{2}}{{R}_{1} + {R}_{2}} {R}_{1} , and$$

$${L}^{′} ↔ {( \frac{{R}_{2}}{{R}_{1} + {R}_{2}} )}^{2} L ,$$

where the parameters corresponding to the series configuration are denoted by a prime symbol. For the series equivalent to the QIE, this results in equation (3.8)

$${I}_{LRR , series} ( ω ) = {( \frac{1}{1 / {R}_{1}^{′} + 1 / i ω {L}^{′}} + {R}_{2}^{′} )}^{- 1} V ( ω ) , \qquad ( 3.8 )$$

which corresponds to the QIE if as defined by equation (3.9)

$${( {R}_{1}^{′} )}^{- 1} ↔ \frac{{e}^{2}}{h} \frac{2 - ζ}{ζ} \qquad ( 3.9 )$$

$${( {R}_{2}^{′} )}^{- 1} ↔ \frac{{e}^{2}}{h} , and$$

$${L}^{′} ↔ \frac{h}{{e}^{2}} \frac{ζ}{2} {τ}_{m} .$$

The physical behavior of the QIE must be considered in interpreting the equivalent circuits. When applying a harmonic voltage over the device, one period of the signal drives in two charging phases (positive and negative bias), instead of having a distinguished charging and discharging phase (positive and zero bias). Both backscattering processes on nuclear spins and thermal relaxation of nuclear spins influence the conductivity. For low frequencies, e.g., long charging phases, polarized nuclear spins in one charging phase can thermally relax before the applied bias switches sign. Therefore, the reduction in conductivity due to backscattering averages out against the increase in conductivity gained from thermal relaxation, and ballistic transport is recovered. Note that the device is operated in the low voltage limit, so the maximum polarization value reached will stay low (equation (2.22)), and ballistic transport at low frequencies cannot be explained by a fully polarized nuclear spin system (offering no backscattering sites).

Upon moving to high frequencies, the average rate at which nuclear spins couple to spin-polarized charge carriers is lower than the rate at which the input voltage switches sign. If backscattering events occur, polarizing nuclear spins, the current driven by thermal relaxation of these spins likely does not fall within the same charging phase of the signal. As the harmonic voltage changes sign, polarized nuclei from the previous phase will now act as additional backscattering sites in the material. This leads to the increased resistance in the high-frequency limit.

One can now compare the parallel and series LRR configurations 1200A and 1200B to this physical interpretation of the QIE. In the parallel LRR configuration 1200A, the low-frequency limit consists of conduction through both resistor R₁ and resistor R₂, which add up to ballistic conductance. The inductor L opens a conductivity path through resistor R₁, and this additional path reduces the overall effective resistance. In the low-frequency limit of the series LRR configuration 1200B, the inductor L′ shorts resistor R₁′, so only resistor R₂′ contributes. The inductor L′ omits a conductivity path through resistor R₁′, which reduces the overall resistance. In the low frequency limit of the QIE, two parallel paths contribute to the current: one path contains the current reduced by backscattering, the other path contains the QIE-driven current which compensates it. In the high frequency limit the compensating-path closes, as the nuclei cannot thermally relax during one full period of the signal. The resistance is increased due to charges being backscattered. Using these considerations and comparing the two circuits to the physical behavior of the QIE, the parallel configuration of FIG. 12A is most sensible.

When the charging and discharging timescales of the QIE device are measured in a circuit, knowledge is needed about how an extracted timescale would relate to τₘ. This is studied using the time response of the inductive model. The system of differential equations governing the time response of the parallel LRR model of FIG. 12A is given by equation (3.10) as:

$$\{ \begin{matrix}I = \frac{V}{{R}_{2}} + {I}_{L} \\ V = L \frac{{dI}_{L}}{dt} + {R}_{1} {I}_{L}\end{matrix} \qquad ( 3.1 )$$

where I_{L} is the current through the inductor, and I, V are the total current and voltage drop of the LRR element, respectively. Solving the differential equation of the LRR element connected to a series resistor Rs gives a valid approximation for long timescales governing the measurement circuit if the inductive timescale by far exceeds the capacitive timescale. This results in equation (3.11) as:

$${τ}_{LRR , par} = L \frac{1 / {R}_{s} + 1 / {R}_{2}}{{R}_{1} / {R}_{s} + {R}_{1} / {R}_{2} + 1} . \qquad ( 3.11 )$$

For R₁, R₂ Rₛ, this reduces to τ_{LRR}≈L/R₁ ↔τₘ (equation (3.6)), under the assumption that the 2D QIE is merely a resealed version of the 1D model. For significant values of Rₛ, τ_{LRR} will be reduced compared to τₘ.

Note that solving the system of differential equations in the series configuration corresponds to equation (3.12) as:

$${τ}_{LRR , series} = {L}^{′} ( \frac{1}{{R}_{1}^{′}} + \frac{1}{{R}_{2}^{′} + {R}_{S}^{′}} ) . \qquad ( 3.12 )$$

Upon applying the conditions of equation (3.7), the above equation transforms back to equation (3.11). This signifies that the total dynamic behavior of the two circuits is equivalent, although the individual parameters scale differently. As the individual parameters are all dependent on a cross-combination of QIE parameters, the models for the QIE can only be fitted as a whole. Recollecting the physical interpretation of the parallel and series combination discussed above, the parallel combination will be used for further analysis. The parameters of the equivalent series combination can be obtained at all times using equation (3.7).

By filling in some characteristic parameters into equation (3.6), an order of magnitude estimate for L is obtained. Using τₘ=1 ms and ζ=1 gives inductor L=25 H (henry). This value would be extremely large: characteristic values of inductors are typically in the μH-mH range. However, this value of inductor L is merely required to obtain an equivalent behavior to the QIE, and must be used in context with the resistors in the parallel configuration.

These elements cannot be tuned separately, only the total response is relevant for the circuit behavior.

### Inductive Effect at the Surface of a Topological Insulator Based on Keldysh-Green Analysis

The previous section considered a grid of 1D QIE elements as a quantitative equivalent to the topological surface state. Next, the topological surface state is described based on the results from Keldysh-Green analysis discussed above. This section defines an electronic circuit element with an equivalent response, showing that hyperfine interaction has an inductive contribution to the surface state current as expected from the qualitative model. For simplicity, assume that nuclear spins are polarized perpendicular to the current direction only, denoted by mean polarization m.

First, consider the harmonic response of the system, in the limit where eV«k_{B}T L/l. This applies when the voltage drop over a mean free path length is small compared to the thermal bias. The inductive behavior of the QIE becomes apparent in this circuit element analysis. The goal of this analysis is to quantify the inductive effect in topological insulators in terms of material parameters and device geometry, allowing for a comparison of the inductive effect in different material systems.

### Equivalent Circuit for Harmonic Excitation

When eV«k_{B}T LL/lₑₗ, the nuclear spin polarization dynamics reduce to equation 4.1 as:

$$\frac{dm}{dt} = \frac{{γ}_{0}^{3 D}}{ℏ} [ \frac{l}{LL} eV - 2 {mk}_{B} T ] . \qquad ( 4.1 )$$

This allows for studying the impedance of the topological surface state under harmonic response, with V(t)=|V|e^{iωt} and m(t)=|m|e^{iω+ϕ}. Equation 4.1 then reduces to equation 4.2 defined as:

$$I ( ω ) = [ G - 4 π {e}^{2} N \frac{{γ}_{0}^{3 D}}{ℏ} {( \frac{l}{LL} )}^{2} \frac{i ω}{i ω {τ}_{m} + 1} ] V ( ω ) , \qquad ( 4.2 )$$

where τₘ=h/2k_{B}Tγ^{3D} is the characteristic nuclear polarization timescale. Equation 4.2 consists of two terms: an Ohmic contribution, and a non-Ohmic (nuclear-polarization induced) contribution. Next, rework this in terms of device geometry. The Ohmic contribution consists of the conductance quantum G₀=e²/h, rescaled by the n_{y}/nₓ. Here, nₓ=lₑₗ/LL is the number of modes in the direction parallel to the current, and n_{y}=k_{F} WW/π is the number of modes perpendicular to the current. Combining this results in produces equation 4.3 as:

$${I}_{Ohmic} = {G}_{Ohmic} V = {G}_{0} \frac{{k}_{F} {l}_{e l}}{π} \frac{WW}{LL} V . \qquad ( 4.3 )$$

The induced current contribution explicitly depends on device geometry through the ratio l/LL, and implicitly through N, which is the total amount of nuclear spins on the disordered surface. Therefore, the term N can be rewritten in terms of the amount of nuclei per unit cell [N]=N·ν₀/WW LLξ, giving equation 4.4 as:

$${I}_{i n d} ( ω ) = 4 π {G}_{0} [ N ] {γ}_{0}^{3 D} \frac{WW}{LL} \frac{ζ l}{{v}_{0}} \frac{i ω}{i ω {τ}_{m} + 1} V ( ω ) . \qquad ( 4.4 )$$

Using the above results, the impedance is defined for a topological surface state according to equation 4.5 as:

$$I ( ω ) = {G}_{Ohmic} V ( 1 - {ζ}^{3 D} \frac{i ω}{i ω {τ}_{m} + 1} ) ≡ {Z}_{TSS}^{- 1} ( ω ) V ( ω ) , \qquad ( 4.5 )$$

where ζ^{3D}=4π²[N]γ₀3Dξl/k_{F}v₀. Note that for ω→0,1_{ind}→0, and for ω→∞, I_{ind} is real and maximized. The out-of-phase component of I_{ind} is maximized at

$$ω = {τ}_{m}^{- 1} .$$

### Substituting

$${γ}_{0}^{3 D}$$

with E_{B} v_{F}/α₀ and E_{F} h v_{F} k_{F} gives equation 4.6 as:

$${ζ}^{3 D} = \frac{π}{2} [ N ] \frac{{v}_{0}}{ξ} {k}_{F} {l ( \frac{{A}_{0}}{ℏ {v}_{F}} )}^{2} . \qquad ( 4.6 )$$

The relative I_{ind} increases linearly with k_{F}, implying that a high carrier density is favorable for observing an induced current due to finite nuclear spin polarization.

However, this is limited by the size of the bulk band gap, as bulk carriers would introduce additional Ohmic shunt channels.

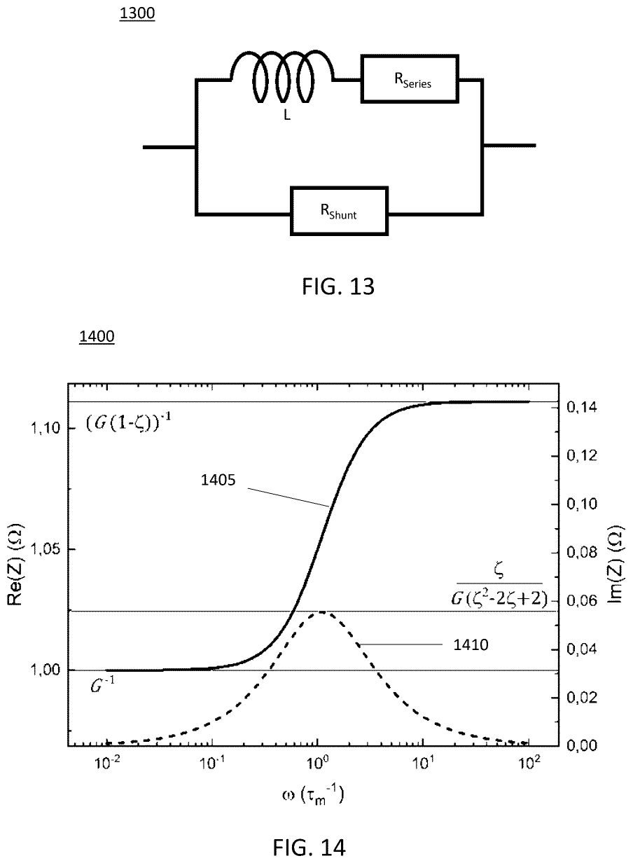

FIG. 13 illustrates an equivalent circuit model 1300, where the topological surface state is represented by two resistors, a series coupled resistor denoted as resistor Rₛₑᵣᵢₑₛ and a resistor Rₛₕᵤₙₜ and an inductor L in parallel.

An impedance with an equivalent frequency response to equation 4.4 is found using a combination of one inductor and resistor parallel to a second resistor (FIG. 13), resulting in equation 4.7 as:

$${I}_{LRR} ( ω ) = ( \frac{1}{i ω L + {R}_{series}} + \frac{1}{{R}_{s hunt}} ) V ( ω ) . \qquad ( 4.7 )$$

Note that a similar response can be obtained by using a resistor in parallel with an inductor, and setting that combination in series to a single resistor. The following analysis assumes the circuit shown in FIG. 13.

This is equivalent to the QIE under the conditions of equation 4.8 as:

$${( {R}_{Series} )}^{- 1} ↔ {G}_{Ohmic} {ζ}^{3 D} = \frac{{G}_{0}}{2} \frac{WW}{LL} [ N ] {( {k}_{F} {l}_{e l} )}^{2} \frac{{v}_{0}}{ξ} {( \frac{{A}_{0}}{ℏ {v}_{F}} )}^{2} \qquad ( 4.8 )$$

$${( {R}_{S hunt} )}^{- 1} ↔ {G}_{Ohmic} ( 1 + {ζ}^{3 D} ) = {G}_{0} \frac{{k}_{F} {l}_{e l}}{π} \frac{WW}{LL} ( 1 - \frac{π}{2} [ N ] \frac{{v}_{0}}{ξ} {k}_{F} {{l}_{e l} ( \frac{{A}_{0}}{ℏ {v}_{F}} )}^{2} ) ,$$

$$L ↔ \frac{{τ}_{m}}{{G}_{Ohmic} {ζ}^{3 D}} = \frac{ℏ}{{k}_{B} T} \frac{8 π}{{G}_{0}} \frac{LL}{WW} \frac{1}{[ N ]} \frac{{ξ}^{3}}{{k}_{F}^{4} {l}_{e l}^{2} {v}_{0}^{3}} {( \frac{ℏ {v}_{F}}{{A}_{0}} )}^{4} .$$

The equivalent circuit model forms the key result of this section: by including hyperfine interaction in a topological surface state with finite nuclear polarization, an inductive component is added to the current-voltage relation.

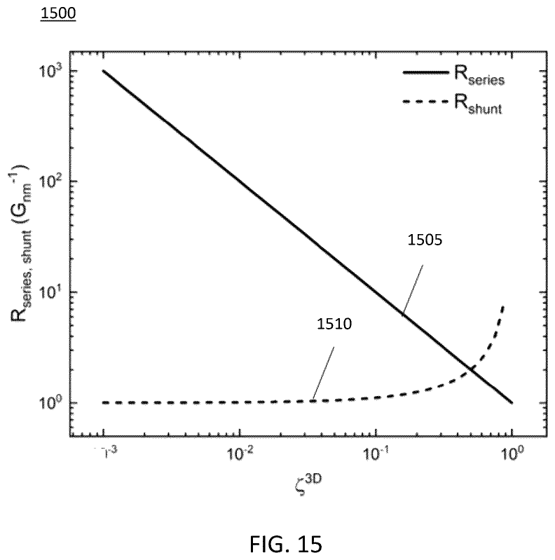

FIG. 15 illustrates a graph 1500 of resistor Rₛₑᵣᵢₑₛ denoted by solid curve 1505 and resistor Rₛₕᵤₙₜ denoted by dashed curve 1510. The resistors are shown in equivalent circuit model 1300 of FIG. 13. FIG. 15 shows the resistors in the equivalent circuit model as a function of the hyperfine coupling strength CD. If the hyperfine coupling energy is zero (ζ^{3D}=0), current through the inductive branch of the circuit element becomes zero, and the equations reduce to the ones for diffusive transport. Then, the efficiency can be characterized of the inductive effect by means of the quality factor at the operating frequency ω=σ⁻¹ in FIG. 14, according to equation (4.9) as:

$$Q = \vert \frac{Im ( {Z}_{TSS} )}{Re ( {Z}_{TSS} )} \vert = \frac{{R}_{s hunt}}{2 {R}_{s eries} + {R}_{s hunt}} ↔ \frac{ζ}{2 - ζ} . \qquad ( 4.9 )$$

FIG. 14 illustrates a frequency response 1400 of the real part denoted by curve 1405 and imaginary part of Z_{TSS} denoted by curve 1410.

The quality factor is enhanced for increased ζ, but the model described in this section breaks down for ζ>1.

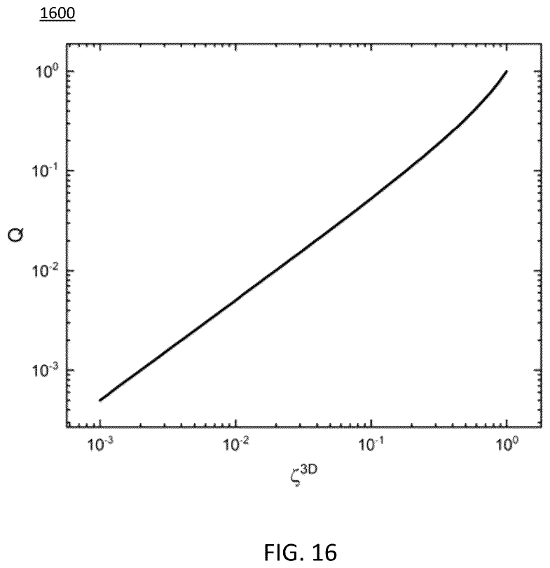

FIG. 16 illustrates a graph 1600 of a quality factor as a function of ζ^{3D}.

### Beyond the Harmonic Response

In the previous section, the low bias limit is defined by eV«k_{B}T LL/lₑₗ.

Although this permits analyzing the device in a single harmonic response and defining the topological surface state as a circuit element with an inductive component, it inherently limits the quality factor: the mean nuclear polarization obtained during each polarization cycle is negligibly small. I_{ind} can be increased by polarizing (charging) the nuclear spins coupled to the TSS in the limit eV«k_{B}T LU/lₑₗ, and depolarizing (discharging) with eV k_{B}T LL/lₑₗ. This ensures an enhanced initial polarization during the discharging phase, while limiting the Ohmic contribution to the current. The inductive character is maintained, as the finite nuclear polarization obtained during charging conserves the direction of the induced current, which equals the direction of the charging current. The goal of this section is to obtain an upper bound on the current generated by the nuclear spins during the discharging phase.

The time dependence is obtained by solving the differential equation in Equation (4.1) under constant voltage bias. This results in equations 4.10, 4.11 and 4.12 as:

$$m ( t ) = ( {m}_{0} - \overline{m} ) {e}^{- \frac{t}{{τ}_{m}}} + \overline{m} \qquad ( 4.1 )$$

$$I = {G}_{Ohmic} V + 2 e [ N ] \frac{WWl ξ}{{v}_{0}} ( \frac{{γ}_{0} eV}{ℏ} \frac{l}{LL} - \frac{{m}_{0}}{{τ}_{m}} ) {e}^{- \frac{t}{{τ}_{m}}} \qquad ( 4.11 )$$

$$where$$

$${τ}_{m} = \frac{L}{l} \frac{ℏ}{{γ}_{0} eV} tanh ( \frac{l}{LL} \frac{eV}{2 {k}_{B} T} ) , \qquad ( 4.12 )$$

and m₀ is the mean nuclear polarization achieved during the charging phase. Assuming an infinite charging time, m₀ equals the steady-state value m⁻ of equation 4.13 as:

$$\overline{m} = tanh ( \frac{l}{LL} \frac{eV}{2 {k}_{B} T} ) . \qquad ( 4.13 )$$

This confirms that charging in the high bias limit for t_{charge}»τₘ, allows for m₀˜1 upon starting the discharge phase, independent of device geometry. This is inherently different from the harmonic excitation in the low bias limit, where both I_{Ohmic} and I_{MD} scale similarly with geometry. Moreover, I_{MD} is independent of V. Therefore, the Ohmic contribution can be cancelled by setting V=0 without altering I_{MD}, leaving Iₜₒₜₐₗ=I_{ind}.

Now, it can be seen that τₘ depends on the bias voltage. If one considers charging in the limit eV»k_{B}T LL/lₑₗ and discharging in the limit eV«k_{B}T LL/lₑₗ, then according to equation 4.14 it is found that:

$${τ}_{charge} = \frac{L L}{l} \frac{ℏ}{{γ}_{0} eV} , {τ}_{discharge} = \frac{ℏ}{2 {γ}_{0} {k}_{B} T} . \qquad ( 4.14 )$$

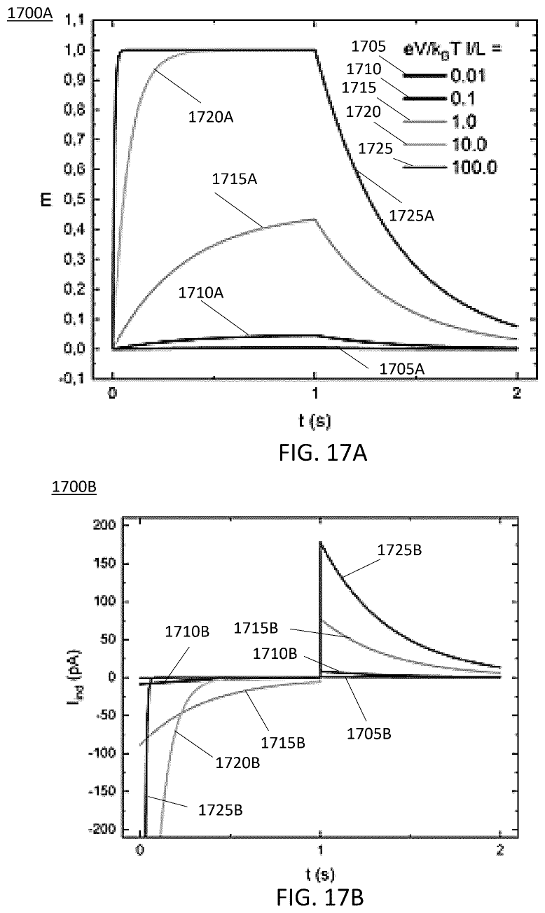

FIGS. 17A and 17B illustrate a quantitative estimate of the induced current as a function of time, on a topological surface of (Bi₁₋ₓSbₓ)₂Te₃, with WW=200 μm, LL =500 nm, lₑₗ=10 nm, γ₀=3.3-10⁻¹² at T=3 K, where FIG. 17A is a graph 1700A of a mean polarization and FIG. 17B is a graph 1700B of current I_{MD}. In FIGS. 17A and 17B, the line 1705 has an eV/k_{B}T I/L=0.01. The line 1710 has an eV/k_{B}T I/LL=0.1. The line 1715 has an eV/k_{B}T I/L=1.0. The line 1720 has an eV/k_{B}T I/LL=10.0. The line 1725 has an eV/k_{B}T I/LL=100.0. The reference numerals 17XX corresponds to the eV/k_{B}T JILL for graphs 1700A and 1700B. The same nomenclature is used for all lines in FIGS. 17A and 17B, where XX is one of 05, 10, 15, 20, and 25.

As posed, eV_{charge}»k_{B}T LL/lₑₗ, then τ_{charge}«τ_{discharge}. The difference in timescales between charging in the high bias limit and discharging in the low bias limit becomes evident in FIGS. 17A and 17B. Here, m and I_{ind}=I−GV are plotted as a function of time, for several V_{charge} values (V_{discharge} equals 0). One way to experimentally verify whether a QIE effect or an RC characteristic is probed during charging, would be to vary V_{charge} and measure whether it is inversely proportional to τ_{charge}.

Similar to the analysis performed on the harmonic response previously discussed, estimate the magnitude of the inductive current when charging with a high voltage bias, and discharging with a low voltage bias. An order-of-magnitude estimate follows from equation 4.1 according to equation 4.15 as:

$$I = {G}_{Ohmic} V - 2 eN \frac{l}{LL} \frac{dm}{dt} = {G}_{Ohmic} V - 2 e [ N ] \frac{WWl ξ}{{v}_{0}} \frac{dm}{dt} \approx {G}_{Ohmic} V + 2 e [ N ] \frac{WWl ξ}{{v}_{0}} \frac{{m}_{0}}{{τ}_{m}} \qquad ( 4.15 )$$

Having estimated an upper bound for I_{ind}, an efficiency ratio is defined by comparing the required current to charge the device to the current generated during discharging. Charging in the high bias limit requires I_{charge}»Gk_{B}TLL/l, resulting in equation 4.16 as:

$$\frac{{I}_{i n d}}{{I}_{c h a r g e}} << \frac{h}{{k}_{B} T} [ N ] \frac{πξ l}{{k}_{F} {v}_{0}} \frac{{m}_{0}}{{τ}_{m}} \qquad ( 4.16 )$$

Summarizing the findings, the ratio is found between induced current and Ohmic current is increased by polarizing the device with eV»k_{B}T LL/lₑₗ, and reducing the bias to eV«k_{B}T LL/lₑₗ upon discharging. The induced current is linearly proportional to the device width, so in order to increase the absolute induced current, increasing the device width is favorable, effectively parallelizing multiple circuit elements. However, the device geometry does not affect the efficiency of the inductive surface state: this is purely influenced by material parameters as shown in equations (4.9) and (4.16).

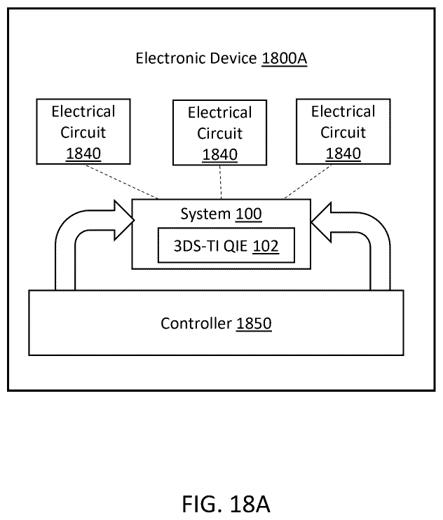

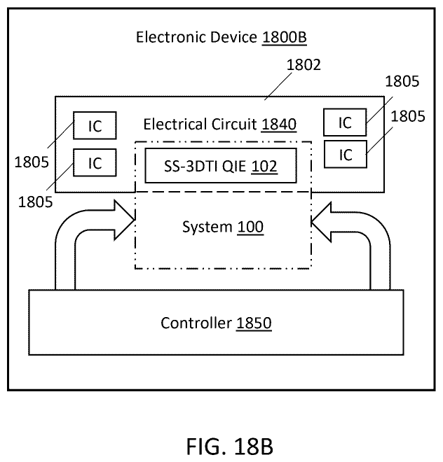

Referring now to FIG. 18A, an electronic device 1800A is provided. The electronic device 1800A may include at least one electrical circuit 1840 and controller 1850. The electronic device 1800A may include at least one system 100 (FIG. 1) or system 700B (FIG. 7B) coupled to the at least one electrical circuit 1840. The controller may be a classical computing device, microprocessor or other processor. The system is a quantum computing device element. Thus, the device may be a quasiclassical device.

By way of non-limiting example, the electronic device 1800A can be one of an application specific integrated circuit (ASIC), a power amp (PA), a focal plane array (FPA), a radar transmitter, a mobile phone, a mobile computer device, an electric motor on an aircraft, or at least a part thereof.

FIG. 18B is an electronic device 1800B with a system having a surface state three-dimensional topological insulator that is integrated on-chip. The electronic device 1800B includes at least one integrated circuit chip 1802 made of semiconductor material. The device 1800B may include many chips. The system 100 (FIG. 1) includes a TSS-3DTI 102 that is integrated on the chip 1802.

The chip 180 may include at least one electrical circuit 1840 that includes integrated circuit (IC) elements 1805 that are integrated on the chip 1802. The system 10θ is configured to harvest heat from the IC elements 1805, for example, such as when storing information. The electronic device 1800B may include a controller 1850 such as to control the current flow in and out of the system, for example. The controller 1850 may also control operations of the electrical circuit 1840.

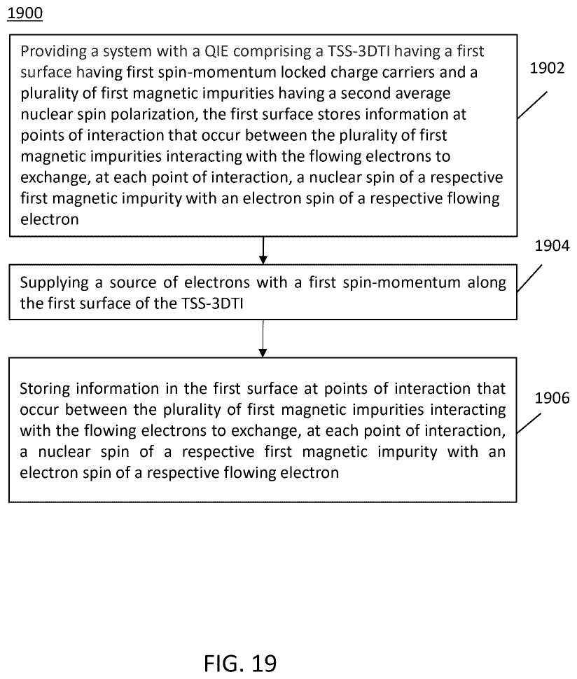

FIG. 19 shows an embodiment of a method 1900 for inductive energy storage. Because the system can be considered as an equivalent circuit containing an inductive element, inductive energy is stored. The method 1900 may include a process for quantum energy storage in a system 100, such as described above in FIG. 1. The method steps may be performed in the order shown or a different order. In some embodiments, one or more steps may be omitted and other steps added. Additionally, one or more steps may be performed contemporaneously.

The method may include, at 1902, flowing electrons in a flow direction along a first surface (i.e., surface 205) of a quantum information engine (QIE) of the system 100. The QIE may include a TSS-3DTI 102, for example. The system may include TSS-3DTIs 102A, 202B, and 702. The method may include, at 1906, storing information in the first surface (i.e., surface 205) at points of interaction that occur between a plurality of first magnetic impurities with a second average nuclear spin polarization interacting with the flowing electrons to exchange, at each point of interaction, a nuclear spin of a respective first magnetic impurity with an electron spin (with a first spin-momentum) of a respective flowing electron, as shown in FIG. 7C.

As described above in relation to FIGS. 8A-8I, information is stored in the first surface when an incident electron has an electron spin that is opposite the average nuclear spin polarization. However, as an electron's spin flips so does the magnetic impurity. Hence, the electron current spin-momentum may then interact with another magnetic impurity.

The method 1900 may include, at 1904, supplying a source of electrons with a first spin-momentum along the first surface of the TSS-3DTI.

In some embodiments, the TSS-3DTI is configured to flow, in the flow direction, second electrons having a second spin-momentum. The TSS-3DTI includes a second surface (i.e., surface 208) that includes second spin-momentum locked charge carriers and a plurality of second magnetic impurities with a first average nuclear spin polarization. The method 1900 may further comprise storing information in the second surface (i.e., surface 208) at second points of interaction that occur between the plurality of second magnetic impurities interacting with the flowing second electrons to exchange, at each second point of interaction, a nuclear spin of a respective second magnetic impurity with an electron spin of a respective flowing second electron.

The method 1900 may further comprise harvesting energy by the TSS-3DTI from the flowing electrons.

The method may further comprise providing the flowing electrons from integrated circuit elements on at least one integrated circuit (IC) chip. The TSS-3DTI is integrated on the IC chip.

Thus, when compared to prior art, such as prior art coherence capacitor designs, the TI may have counter-propagating topological surface states with opposite spins, while the bulk stays insulating. The spin of the topological surface states couples to the nuclear spins along the surfaces of the TI via hyperfine interaction. This may provide for a transfer of magnetic moment, with an accompanying backscattering of the electrons. As a result, a charge current due to electric potential difference or thermal gradient may give rise to coherently aligned nuclear spins.

Embodiments disclosed herein are able to extract available entropy out of the nuclear spin subsystem and utilize the information by converting the thermal energy into electrical work. When the electric potential applied to the specialized leads is removed, the finite nuclear spin polarization drives a charge current in the same direction as the charge current applied when the electric potential was present to charge the device. This is a characteristic behavior of an inductive circuit element. A reverse voltage bias, or an external load may be used to extract electrical work from this induced charge current.

Unless otherwise defined, all terms (including technical and scientific terms) used herein have the same meaning as commonly understood by one of ordinary skill in the art to which embodiments belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In particular, unless specifically stated otherwise as apparent from the discussion, it is appreciated that throughout the description, discussions utilizing terms such as “processing” or “computing” or “calculating” or “determining” or “displaying” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such data storage, transmission or display devices.

The terminology used herein is for the purpose of describing particular embodiments only and is not intended to be limiting. As used herein, the singular forms “a,” “an,” and “the” are intended to include the plural forms as well, unless the context clearly indicates otherwise. Furthermore, to the extent that the terms “including,” “includes,” “having,” “has,” “with,” or variants thereof are used in either the detailed description and/or the claims, such terms are intended to be inclusive in a manner similar to the term “comprising.” Moreover, unless specifically stated, any use of the terms first, second, etc., does not denote any order or importance, but rather the terms first, second, etc., are used to distinguish one element from another. As used herein the expression “at least one of A and B,” will be understood to mean only A, only B, or both A and B.

While various disclosed embodiments have been described above, it should be understood that they have been presented by way of example only, and not limitation.

Numerous changes, omissions and/or additions to the subject matter disclosed herein can be made in accordance with the embodiments disclosed herein without departing from the spirit or scope of the embodiments. Also, equivalents may be substituted for elements thereof without departing from the spirit and scope of the embodiments. In addition, while a particular feature may have been disclosed with respect to only one of several implementations, such feature may be combined with one or more other features of the other implementations as may be desired and advantageous for any given or particular application. Furthermore, many modifications may be made to adapt a particular situation or material to the teachings of the embodiments without departing from the scope thereof.

Therefore, the breadth and scope of the subject matter provided herein should not be limited by any of the above explicitly described embodiments. Rather, the scope of the embodiments should be defined in accordance with the following claims and their equivalents.

### REFERENCES

The following references are incorporated herein by reference in full.
[1]M. Z. Hasan and C. L. Kane, “Colloquium: Topological insulators,” Reviews of Modern Physics, vol. 82, pp. 3045-3067, Nov. 2010. Publisher: American Physical Society.
[2]J. Tian, S. Hong, I. Miotkowski, S. Datta, and Y. P. Chen, “Observation of current-induced, long-lived persistent spin polarization in a topological insulator: A rechargeable spin battery,” Science Advances, vol. 3, p. e1602531, Apr. 2017. Publisher: American Association for the Advancement of Science Section: Research Article.
[3]L. Fu, C. L. Kane, and E. J. Mele, “Topological Insulators in Three Dimensions,” Physical Review Letters, vol. 98, p. 106803, Mar. 2007.
[4]J. E. Moore and L. Balents, “Topological invariants of time-reversal-invariant band structures,” Physical Review B, vol. 75, p. 121306, Mar. 2007.
[5]H. B. Nielsen and M. Ninomiya, “The Adler-Bell-Jackiw anomaly and Weyl fermions in a crystal,” Physics Letters B, vol. 130, pp. 389-396, Nov. 1983.
[6]A. A. Burkov and D. G. Hawthorn, “Spin and Charge Transport on the Surface of a Topological Insulator,” Physical Review Letters, vol. 105, p. 066802, Aug. 2010.
[7]P. Schwab, R. Raimondi, and C. Gorini, “Spin-charge locking and tunneling into a helical metal,” EPL (Europhysics Letters), vol. 93, p. 67004, Mar. 2011.
[8]X. Liu and J. Sinova, “Reading Charge Transport from the Spin Dynamics on the Surface of a Topological Insulator,” Physical Review Letters, vol. 111, p. 166801, Oct. 2013.
[9]J. Rammer, “Quantum field-theoretical methods in transport theory of metals,” Reviews of Modern Physics, vol. 58, no. 2, pp. 323-359, 1986.
[10]A. Bozkurt, B. Pekerten, and I. Adagideli, “Work extraction and Landauer's principle in a quantum spin Hall device”, Phys. Rev. B vol. 97, 245414 (Jun. 15, 2018).
[11]J. Voerman, “Putting a spin on topological matter”, University of Twente, PhD thesis, 2019.
[12]D. Teweldebrhan, V. Goyal, and A. Balandin, “Exfoliation and characterization of bismuth telluride atomic quintuples and quasi-two-dimensional crystals”, Nano letters 10, 1209-1218 (Mar. 5, 2010).
[13]J. Zhang, C.-Z. Chang, Z. Zhang, J. Wen, X. Feng, K. Li, M. Liu, K. He, L. Wang, X. Chen, et al., “Band structure engineering in (BiiₓSbₓ)₂Te₃ ternary topological insulators”, Nature communications 2, 1-6 (2011).
[14]I. Zutid, J. Fabian, and S. Sarma, “Spintronics: Fundamentals and applications”, Reviews of modern physics 76, 323 (2004).
[15]X. Hu, R. de Sousa, and S. Sarma, “Decoherence and dephasing in spin-based solid state quantum computers”, in Foundations Of Quantum Mechanics In The Light Of New Technology: ISQM Tokyo 01 (World Scientific, 2002), pp. 3-11.
[16]O. Zobel, “Theory and design of uniform and composite electric wave-filters”, The Bell System Technical Journal 2, 45 (1923).
[17]L. Fu and C. L. Kane, “Topological insulators with inversion symmetry”, Phys. Rev. B 76, 045302 (2007).
[18]J. E. Moore and L. Balents, “Topological invariants of time-reversal-invariant band structures”, Phys. Rev. B 75, 121306 (2007).
[19]H. B. Nielsen and M. Ninomiya, “The Adler-Bell-Jackiw anomaly and Weyl fermions in a crystal”, Physics Letters B 130, 389-396 (1983).
[20]P. Schwab, R. Raimondi, and C. Gorini, “Spin-charge locking and tunneling into a helical metal”, Europhysics Letters 93, 67004 (2011).
[21]X. Liu and J. Sinova, “Reading Charge Transport from the Spin Dynamics on the Surface of a Topological Insulator”, Phys. Rev. Lett. 111, 166801 (2013).
[22]A. M. Bozkurt, B. Pekerten, and I. Adagideli, “Work extraction and Landauer's principle in a quantum spin Hall device”, Physical Review B 97, 245414 (2018).
[23]J. Rammer and H. Smith, “Quantum field-theoretical methods in transport theory of metals”, Rev. Mod. Phys. 58, 323-359 (1986).
[24]J. Zhang, C.-Z. Chang, Z. Zhang, J. Wen, X. Feng, K. Li, M. Liu, K. He, L. Wang, X. Chen, et al., “Band structure engineering in (Bil-xSbx) 2Te3 ternary topological insulators”, Nature communications 2, 574 (2011).
[25]C.-X. Liu, H. Zhang, B. Yan, X.-L. Qi, T. Frauenheim, X. Dai, Z. Fang, and S.-C. Zhang, “Oscillatory crossover from two-dimensional to three-dimensional topological insulators”, Physical review B 81, 041307 (2010).

We claim:

1. A system comprising:
a capacitive quantum information engine (CQIE) including:
a first quantum anomalous Hall insulator (QAHI) having spin-up electrons propagating in a first direction and includes first edge that contain first spin-momentum locked electron channels that prohibit backscattering of spin-down electrons; and
a second QAHI having the spin-down electrons propagating in a second direction and includes second edge that contain second spin-momentum locked electron channels that prohibit backscattering of the spin-up electrons, the first direction being one of a clockwise direction and a counterclockwise direction.

2. The system of claim 1, wherein the CQIE includes a nuclear spin direction of magnetic impurities to spin flip a respective electron to an opposite spin direction associated with electrons of the first QAHI and the second QAHI; and results in a respective magnetic impurity to spin flip to one of store energy and discharge energy.

3. The system of claim 2, further comprising:
a plurality of first contacts coupled to the first QAHI, each first contact coupled to a respect energy source of a plurality of first energy sources; and
a plurality of second contacts coupled to the second QAHI, each second contact coupled to a respect energy source of a plurality of second energy sources,
wherein the magnetic impurities includes:
first magnetic impurities in the first QAHI at a junction of the first QAHI and the second QAHI, and
second magnetic impurities in the second QAHI at the junction.

4. The system of claim 3, further comprising:
the plurality of first energy sources;
the plurality of second energy sources;
a plurality of first tunable loads that have a first voltage potential range; and
a second plurality of tunable loads that have a second voltage potential range,
the first voltage potential range is tuned to be one of higher and lower than the second voltage potential range to control the flow of the spin-up electrons to a respective contact of the plurality of first contacts and the spin-down electrons to a respective contact of the plurality of second contacts.

5. The system according to claim 2, further comprising a quantum spin Hall insulator (QSHI) having a first lead and a second lead and the magnetic impurities,
wherein:
the first QAHI is the first lead;
the second QAHI is the second lead; and
the first and second QAHIs provide opposite spin and opposite chirality.

6. The system of claim 5, further comprising:
a plurality of first contacts coupled to the first QAHI, each first contact coupled to a respect energy source of a plurality of first energy sources; and
a plurality of second contacts coupled to the second QAHI, each second contact coupled to a respect energy source of a plurality of second energy sources.

7. The system of claim 6, further comprising:
the plurality of first energy sources;
the plurality of second energy sources;
a plurality of first tunable loads that have a first voltage potential range; and
a second plurality of tunable loads that have a second voltage potential range,
the first voltage potential range is tuned to be one of higher and lower than the second voltage potential range to control the flow of the spin-up electrons to a respective contact of the plurality of first contacts and the spin-down electrons to a respective contact of the plurality of second contacts.

8. The system according to claim 7, wherein the first voltage potential range and the second voltage potential range provide voltage potential differentials across the plurality of first tunable loads and the plurality of second tunable loads.

9. The system according to claim 5, wherein:
the first QAHI has a first filling factor;
the second QAHI has a second filling factor different from the first filling factor;
the QSHI comprises at least one of nuclear spins and magnetic impurities that allow the first QAHI and the second QAHI to spin-flip;
the QSHI comprises a first edge adjacent to the first QAHI and a second edge adjacent to the second QAHI, the first edge being parallel to the second edge;
the QSHI comprises a third edge and a fourth edge that are parallel to each other and orthogonal to the first edge and the second edge; and
the nuclear spins are only located at one of the third edge and the fourth edge of the QSHI.

10. The system according to claim 2, wherein:
the capacitive quantum information engine is one of a memristive device, a multiplexing power supply switch and a nonvolatile memory; and
further comprising:
a plurality of first selectable contacts coupled to the first QAHI; and
a plurality of second selectable contacts coupled to the second QAHI.

11. An electronic device comprising:
at least one electrical circuit; and
a system with a capacitive quantum information engine (CQIE) of claim 1 coupled to the at least one electrical circuit for storing energy in response to a spin flip.

12. The device of claim 11, wherein the capacitive quantum information engine is one of a memristive device, a multiplexing power supply switch, and a nonvolatile memory.

13. The device of claim 11, wherein the CQIE includes a nuclear spin direction of magnetic impurities to spin flip a respective electron to an opposite spin direction associated with electrons of a first quantum anomalous Hall insulator (QAHI) and a second QAHI; and
results in a respective magnetic impurity to spin flip to one of store energy and discharge energy.

14. The device according to claim 13, wherein the capacitive quantum information engine further comprises:
a quantum spin Hall insulator (QSHI) having a first lead and a second lead and the magnetic impurities,
wherein:
the first QAHI is the first lead;
the second QAHI is the second lead; and
the first and second QAHIs provide opposite spin and opposite chirality.

15. The device of claim 13, wherein the system further comprises:
a plurality of first contacts coupled to the first QAHI, each first contact coupled to a respect energy source of a plurality of first energy sources; and
a plurality of second contacts coupled to the second QAHI, each second contact coupled to a respect energy source of a plurality of second energy sources,
wherein the magnetic impurities includes:
first magnetic impurities in the first QAHI at a junction of the first QAHI and the second QAHI, and
second magnetic impurities in the second QAHI at the junction.

16. The device of claim 15, further comprising:
the plurality of first energy sources;
the plurality of second energy sources;
a plurality of first tunable loads that have a first voltage potential range; and
a second plurality of tunable loads that have a second voltage potential range,
the first voltage potential range is tuned to be one of higher and lower than the second voltage potential range to control the flow of the spin-up electrons to a respective contact of the plurality of first contacts and the spin-down electrons to a respective contact of the plurality of second contacts.

17. The device of claim 11, further comprising:
a controller coupled to the system,
wherein:
the at least one electrical circuit comprises a plurality of electrical circuits;
the system is a multiplexing power supply switch with multiport contacts coupled to the plurality of electrical circuits; and
the controller to control the system to multiplex a supply of power to the plurality of electrical circuits.

18. The device of claim 11, further comprising:
a controller coupled to the system,
wherein:
the at least one electrical circuit comprises a plurality of electrical circuits;
the system is a nonvolatile memory with multiport contacts coupled to the plurality of electrical circuits; and
the controller to control information storage supplied via the nonvolatile memory for any one of a selected electrical circuit of the plurality of electrical circuits.

19. A method for quantum energy storage, comprising:
providing a capacitive quantum information engine (CQIE) of claim 1;
supplying current along the at least one edge of the CQIE; and
flipping nuclear spin direction of magnetic impurities of the CQIE to store quantum energy.

20. The method of claim 19, wherein the CQIE includes a quantum spin Hall insulator (QSHI) between a first quantum anomalous Hall insulator (QAHI) and a second QAHI and magnetic impurities along an edge of the QSHI and wherein the flipping includes flipping the nuclear spin direction of a respective electron to an opposite spin direction associated with electrons of one of the first QAHI and the second QAHI.

21. The method of claim 19, wherein:
the magnetic impurities includes first magnetic impurities and second magnetic impurities;
the CQIE includes a first quantum anomalous Hall insulator (QAHI) having the first magnetic impurities and a second QAHI having the second magnetic impurities,
the first magnetic impurities and the second magnetic impurities are at a junction associated with the first QAHI and the second QAHI, and
the flipping comprises:
flipping a first respective electron to an opposite spin direction associated with electrons of the second QAHI in response to interaction of the first respective electron with the first magnetic impurities; and
flipping a second respective electron to an opposite spin direction associated with electrons of the second QAHI in response to interaction of the second respective electron with the second magnetic impurities.
